(19) United States
(12) Patent Application Publication
(10) Pub. No.: US 2024/0032265 A1
(43) Pub. Date: Jan. 25, 2024

(54) POWER CARD

(71) Applicant: DENSO CORPORATION, Kariya-city (JP)

(72) Inventors: Yuta HASHIMOTO, Kariya-city (JP); Tomohisa SANO, Kariya-city (JP); Shoichiro OMAE, Kariya-city (JP); Takanori KAWASHIMA, Kariya-city (JP)

(73) Assignee: DENSO CORPORATION, Kariya-city (JP)

(21) Appl. No.: 18/481,534

(22) Filed: Oct. 5, 2023

Related U.S. Application Data
(63) Continuation of application No. PCT/JP2022/013106, filed on Mar. 22, 2022.

(30) Foreign Application Priority Data
Apr. 9, 2021 (JP) 2021-066704

(51) Int. Cl. H05K 7/20

(52) U.S. Cl. CPC H05K 7/20927

(57) ABSTRACT

A power card, which is to be aligned in a height direction with a cooling unit in which a refrigerant flows in an inner space extending in a lateral direction, includes a plurality of switches, a resin portion, and a plurality of external connection terminals. The switches are aligned in a vertical direction perpendicular to each of the lateral direction and the height direction. The resin portion covers each of the switches. The external connection terminals are electrically connected to the respective switches and each have a portion exposed from the resin portion.

### CROSS REFERENCE TO RELATED APPLICATIONS

The present application is a continuation application of International Patent Application No. PCT/JP2022/013106 filed on Mar. 22, 2022, which designated the U.S. and claims the benefit of priority from Japanese Patent Application No. 2021-066704 filed on Apr. 9, 2021. The entire disclosures of all of the above applications are incorporated herein by reference.

### TECHNICAL FIELD

The present disclosure relates to a power card to be provided in a cooler.

### BACKGROUND

There is known a semiconductor module having two insulated gate bipolar transistors (IGBTs) and a sealing resin body covering the IGBTs.

### SUMMARY

The present disclosure provides a power card, which is to be aligned with a cooling unit in a height direction, including a plurality of switches aligned in a vertical direction perpendicular to the height direction; a resin portion covering each of the plurality of switches; and a plurality of external connection terminals electrically connected to the plurality of respective switches and each having a portion exposed from the resin portion.

### BRIEF DESCRIPTION OF THE DRAWINGS

Features and advantages of the present disclosure will become more apparent from the following detailed description made with reference to the accompanying drawings, in which:

FIG. 1 is a circuit diagram illustrating an in-vehicle system;

FIG. 2 is an exploded perspective view of the power card;

FIG. 3 is a perspective view of the power card;

FIG. 4 is a side view of the power card;

FIG. 5 is a plan view of the power card;

FIG. 6 is a cross-sectional view along a line VI-VI illustrated in FIG. 5;

FIG. 7 is a cross-sectional view along a line VII-VII illustrated in FIG. 5;

FIG. 8 is an internal view of a first conductive plate;

FIG. 9 is an internal view of a second conductive plate;

FIG. 10 is a plan view illustrating a state where the second conductive plate is provided with semiconductor chips and solders;

FIG. 11 is a plan view illustrating a state where the second conductive plate is provided with terminal blocks and connection terminals;

FIG. 12 is a plan view illustrating a state where the second conductive plate is provided with the first conductive plate;

FIG. 13 is a cross-sectional view for illustrating a current-carrying path;

FIG. 14 is a cross-sectional view for illustrating the current-carrying path;

FIG. 15 is a plan view for illustrating the current-carrying path;

FIG. 16 is a perspective view for illustrating the current-carrying path;

FIG. 17 is a perspective view illustrating a power module;

FIG. 18 is a plan view of the power module;

FIG. 19 is a side view of the power module;

FIG. 20 is a perspective view illustrating a state where a phase bus bar, a P bus bar, and an N bus bar are connected to three semiconductor modules;

FIG. 21 is an upper view illustrating a state where the phase bus bar, the P bus bar, and the N bus bar are connected to the three semiconductor modules;

FIG. 22 is a side view illustrating the state where the phase bus bar, the P bus bar, and the N bus bar are connected to the semiconductor modules;

FIG. 23 is a side view illustrating the state where the phase bus bar, the P bus bar, and the N bus bar are connected to the semiconductor modules;

FIG. 24 is an external view illustrating a modification of the first conductive plate;

FIG. 25 is an external view illustrating a modification of the second conductive plate;

FIG. 26 is a cross-sectional view illustrating a modification of the power card; and

FIG. 27 is a cross-sectional view illustrating a modification of the power card.

### DETAILED DESCRIPTION

In a semiconductor module having multiple insulated gate bipolar transistors (IGBTs) as switches and a sealing resin body covering the IGBTs, a temperature difference may occur between the multiple IGBTs.

The present disclosure provides a power card which is capable of suppressing an occurrence of temperature difference between multiple switches.

A power card according to an aspect of the present disclosure is a power card provided in such a mode as to be aligned in a height direction with a cooling unit in which a refrigerant flows in an inner space extending in a lateral direction, the height direction being perpendicular to the lateral direction, the power card including:
a plurality of switches aligned in a vertical direction perpendicular to each of the lateral direction and the height direction;
a resin portion covering each of the plurality of switches; and
a plurality of external connection terminals electrically connected to the plurality of respective switches and each having a portion exposed from the resin portion.

In such a configuration, it is possible to suppress an occurrence of a difference in heat exchange efficiency between the plurality of switches, which are covered with the one resin portion, with the refrigerant. As such, an occurrence of a temperature difference between the plurality of switches is suppressed.

Multiple embodiments for implementing the present disclosure will be described hereinafter with reference to the drawings. In the individual embodiments, a repetitive description of a part corresponding to a matter described in the preceding embodiment may be omitted by giving the same reference numeral thereto. In each of the embodiments, when only a part of a configuration is described, to another part of the configuration, another embodiment previously described is applicable.

It is possible to combine parts that are explicitly stated to be specifically combinable in each embodiment. In addition, it may also be possible to partially combine the individual embodiments with each other, the embodiment with a modification, and the individual modifications with each other even though it is not explicitly stated that the combination is possible, as long as the combination has no particular problem.

### First Embodiment

### In-Vehicle System

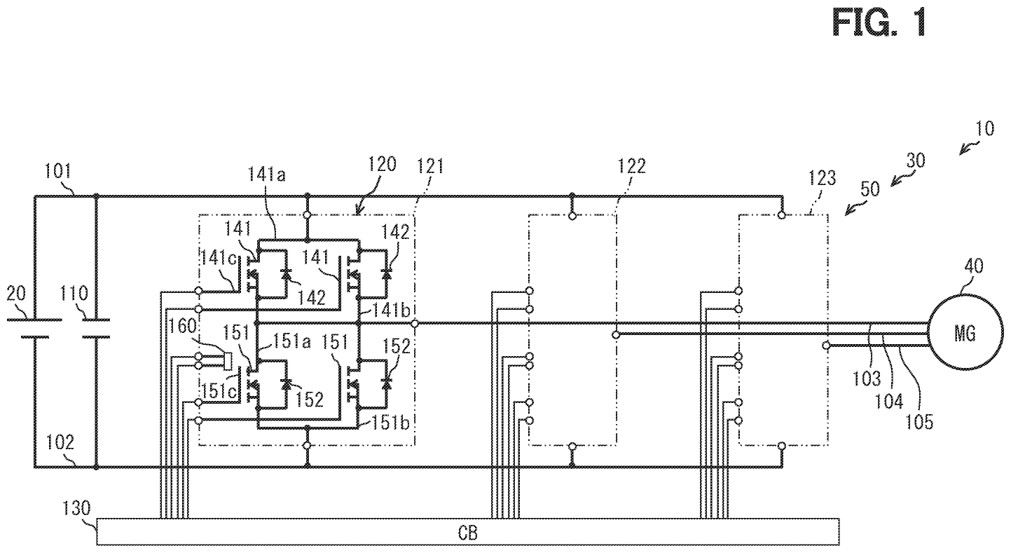

First, on the basis of FIG. 1, an in-vehicle system 10 will be described. The in-vehicle system 10 forms a system for an electric vehicle. The in-vehicle system 10 has a battery 20, a power conversion unit 30, and a motor 40.

The in-vehicle system 10 also has a plurality of ECUs not shown. The plurality of ECUs transmit/receive signals to/from each other via bus wiring. The plurality of ECUs cooperate to control the electric vehicle. Under the control of the plurality of ECUs, high-speed operation and regeneration of the motor 40 according to a SOC of the battery 20 is controlled. The SOC is an abbreviation of state of charge. The ECU is an abbreviation of an electronic control unit.

The battery 20 has a plurality of secondary cells. The plurality of secondary cells are included in a cell stack connected in series. The SOC of the cell stack corresponds to the SOC of the battery 20. As each of the secondary cells, a lithium ion secondary cell, a nickel-hydrogen secondary cell, an organic radical cell, or the like can be adopted.

A power conversion device 50 included in the power conversion unit 30 performs power conversion between the battery 20 and the motor 40. The power conversion device 50 converts DC power from the battery 20 to AC power. The power conversion device 50 convers the AC power generated by electricity generation (regeneration) by the motor 40 to the DC power.

The motor 40 is connected to a vehicle shaft of the electric vehicle not shown. Rotational energy of the motor 40 is transmitted to steering wheels of the electric vehicle via axles. Conversely, rotational energy of the steering wheels is transmitted to the motor 40 via the axles. In the drawings, the motor 40 is represented by MG.

The motor 40 performs high-speed operation with the AC power supplied from the power conversion device 50. Thus, a propulsive force is given to the steering wheels. Meanwhile, the motor 40 is regenerated by the rotational energy transmitted from the steering wheels. The AC power generated by the regeneration is converted to the DC power in the power conversion device 50. The DC power is supplied to the battery 20. The DC power is supplied also to various electric loads mounted in the electric vehicle.

### Power Conversion Device

Next, the power conversion device 50 will be described. The power conversion device 50 includes an inverter. The inverter converts the DC power from the battery 20 to the AC power. The AC power is supplied to the motor 40. The inverter also converts the AC power generated from the motor 40 to the DC power. The DC power is supplied to the battery 20 and to the various electric loads.

As illustrated in FIG. 1, the power conversion device 50 includes a P bus bar 101 and an N bus bar 102. To each of the P bus bar 101 and the N bus bar 102, the battery 20 is connected. The P bus bar 101 is connected to a positive electrode of the battery 20. The N bus bar 102 is connected to a negative electrode of the battery 20.

The power conversion device 50 also includes a U-phase bus bar 103, a V-phase bus bar 104, and a W-phase bus bar 105. To these 3-phase bus bars, the motor 40 is connected. In FIG. 1, connection points of conductive members such as these various bus bars are indicated by white circles. These connection points are electrically connected by, e.g., bolts, welding, or the like.

The power conversion device 50 has a smoothing capacitor 110, a power card 120, and a control substrate 130.

The smoothing capacitor 110 has two electrodes. Of these two electrodes, one is connected to the P bus bar 101. Of the two electrodes, another is connected to the N bus bar 102.

As the power card 120, U-phase to W-phase semiconductor modules 121 to 123 are present. Each of the U-phase to W-phase semiconductor modules 121 to 123 has high-side switches 141 and high-side diodes 142. Each of these three semiconductor modules has low-side switches 151 and low-side diodes 152.

Each of the U-phase to W-phase semiconductor modules 121 to 123 has an equivalent configuration. In FIG. 1, of these three semiconductor modules, only the U-phase semiconductor module 121 is specifically illustrated.

In the present embodiment, as the high-side switches 141 and the low-side switches 151, n-channel MOSFETs are adopted.

To a drain 141a of each of the high-side switches 141, a cathode of each of the high-side diodes 142 is connected. To a source 141b of each of the high-side switches 141, an anode of each of the high-side diodes 142 is connected. Thus, to the high-side switches 141, the high-side diodes 142 are connected in antiparallel. The drain 141a and the source 141b of each of the high-side switches 141 correspond to a first electrode and a second electrode.

To a drain 151a of each of the low-side switches 151, a cathode of each of the low-side diodes 152 is connected. To a source 151b of each of the low-side switches 151, an anode of each of the low-side diodes 152 is connected. Thus, to the low-side switches 151, the low-side diodes 152 are connected in antiparallel. The drain 151a and the source 151b of each of the low-side switches 151 correspond to a third electrode and a fourth electrode.

Each of the U-phase to W-phase semiconductor modules 121 to 123 has the two high-side switches 141 and the two low-side switches 151. Additionally, each of the U-phase to W-phase semiconductor modules 121 to 123 has the two high-side diodes 142 and the two low-side diodes 152.

The two high-side switches 141 have the respective drains 141a connected to each other, while having the respective sources 141b connected to each other. Thus, the two high-side switches 141 are connected in parallel.

The two low-side switches 151 have the respective drains 151a connected to each other, while having the respective sources 151b connected to each other. Thus, the two low-side switches 151 are connected in parallel.

The sources 141b of the two high-side switches 141 connected in parallel are connected to the drains 151a of the two low-side switches 151 connected in parallel. Thus, the two high-side switches 141 connected in parallel and the two low-side switches 151 connected in parallel are connected in series.

As shown in FIG. 1, the drains 141a of the two high-side switches 141 connected in parallel are connected to the P bus bar 101. The sources 151b of the two low-side switches 151 connected in parallel are connected to the N bus bar 102. Thus, the two low-side switches 151 connected in parallel to the two high-side switches 141 connected in parallel are sequentially connected in series from the P bus bar 101 toward the N bus bar 102.

Midpoints between the high-side switches 141 and the low-side switches 151 which are included in the U-phase semiconductor module 121 are connected to a U-phase stator coil of the motor 40 via the U-phase bus bar 103. Midpoints between the high-side switches 141 and the low-side switches 151 which are included in the V-phase semiconductor module 122 are connected to a V-phase stator coil via the V-phase bus bar 104. Midpoints between the high-side switches 141 and the low-side switches 151 which are included in the W-phase semiconductor module 123 are connected to a W-phase stator coil via the W-phase bus bar 105. Thus, the battery 20 and the motor 40 are connected via the 3-phase semiconductor modules.

Respective gates 141c of the high-side switches 141 and respective gates 151c of the low-side switches 151 which are respectively included in the U-phase to W-phase semiconductor modules 121 to 123 are connected to the control substrate 130. Thus, the 3-phase semiconductor modules are connected to the control substrate 130. The gate 141c of each of the high-side switches 141 corresponds to a first control electrode. The gate 151c of each of the low-side switches 151 corresponds to a second control electrode.

Each of the U-phase to W-phase semiconductor modules 121 to 123 has a temperature sensor 160. This temperature sensor 160 is also connected to the control substrate 130.

The control substrate 130 includes a gate driver. The control substrate 130 or another substrate includes one of the plurality of ECUs. In the drawings, the control substrate 130 is represented by CB.

The ECU electrically connected to the gate driver generates a control signal that controls the high-side switches 141 and the low-side switches 151 between an energized state and an interrupted state. As the control signal, the ECU generates a pulse signal. The ECU adjusts an on-duty ratio and a frequency of the pulse signal. The on-duty ratio and frequency are determined on the basis of an output of a current sensor or a rotation angle sensor not shown, a target torque of the motor 40, the SOC of the battery 20, or the like.

The control signal generated from the ECU is amplified by the gate driver. The amplified control signal is input to each of the gates 141c of the high-side switches 141 and the gates 151c of the low-side switches 151.

When the motor 40 is caused to perform the high-speed operation, the ECU performs PWM control on the switches included in the 3-phase semiconductor modules by using the control signal. Thus, a 3-phase alternating current is generated in the power conversion device 50.

When the motor 40 performs power generation (regeneration), the ECU stops, e.g., outputting of the control signal. Consequently, the alternating current generated by the power generation passes through the diodes included in the 3-phase semiconductor modules. As a result, the AC power is converted to the DC power.

### Power Card

Next, a configuration of the power card 120 will be described. In other words, configurations of the U-phase to W-phase semiconductor modules 121 to 123 will be described.

Hereinafter, it is assumed that three directions having perpendicular relationships therebetween are an x-direction, a y-direction, and a z-direction. In the drawings, writing of the “directions” is omitted, and x, y, and z are simply written. The x-direction corresponds to a lateral direction. The y-direction corresponds to a vertical direction. The z-direction corresponds to a height direction.

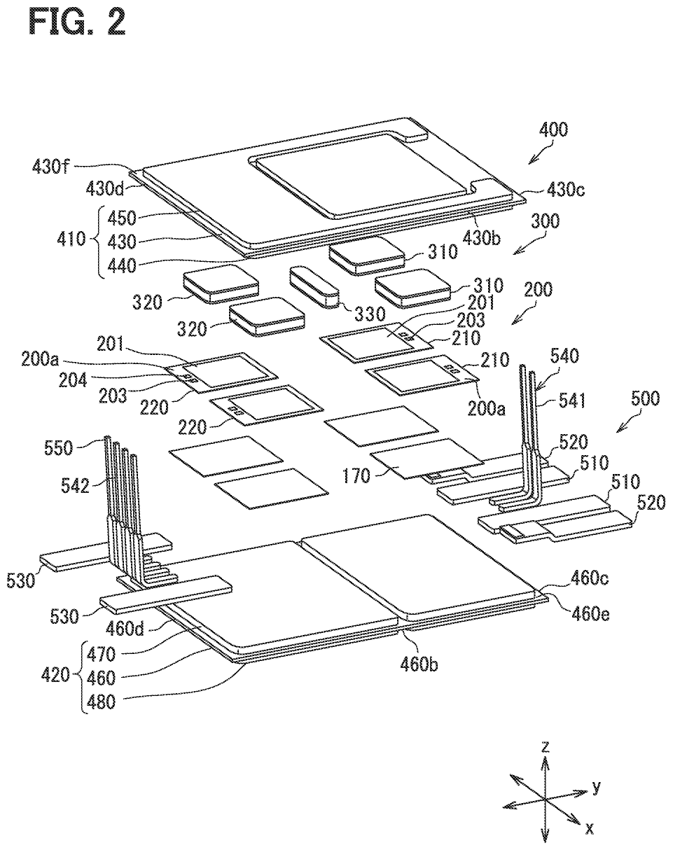

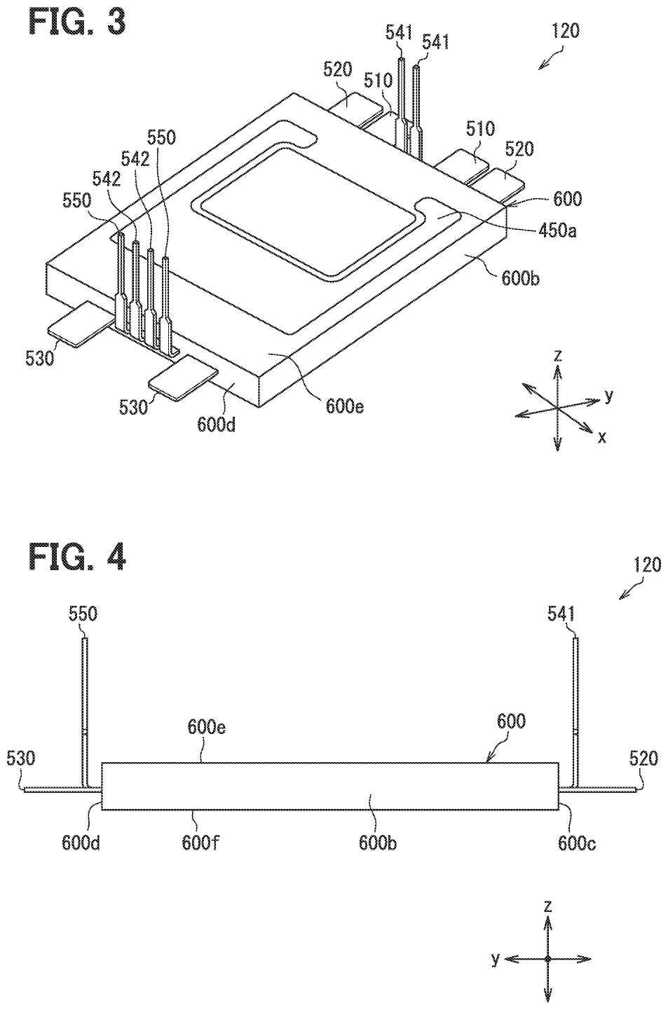

As illustrated in FIG. 2, the power card 120 has semiconductor chips 200, terminal blocks 300, conductive plates 400, and connection terminals 500. As illustrated in FIGS. 3 to 5, the power card 120 has a covering resin 600.

In the semiconductor chips 200, semiconductor elements such as the switches and the diodes each described heretofore are formed. The terminal blocks 300 and the conductive plates 400 perform a function of electrically connecting the semiconductor elements. The connection terminals 500 perform a function of electrically connecting the semiconductor elements, the various bus bars, and the control substrate 130 to each other. The covering resin 600 performs a function of not only covering and protecting, but also integrally connecting the semiconductor chips 200, the terminal blocks 300, the conductive plates 400, and the connection terminals 500. Each of the connection terminals 500 corresponds to an external connection terminal. The covering resin 600 corresponds to a resin portion.

### Semiconductor Chip

The semiconductor chips 200 include first semiconductor chips 210 and second semiconductor chips 220. Each of the first semiconductor chips 210 and the second semiconductor chips 220 is formed of a semiconductor such as Si or a wide-gap semiconductor such as SiC. Materials of the first semiconductor chips 210 and the second semiconductor chips 220 may be or may not be the same.

The first semiconductor chips 210 are formed with the high-side switches 141 and the high-side diodes 142. The high-side diodes 142 may be parasitic diodes of the high-side switches 141 or may also be diodes other than those.

The second semiconductor chips 220 are formed with the low-side switches 151 and the low-side diodes 152. The low-side diodes 152 may be parasitic diodes of the low-side switches 151 or may also be diodes other than those.

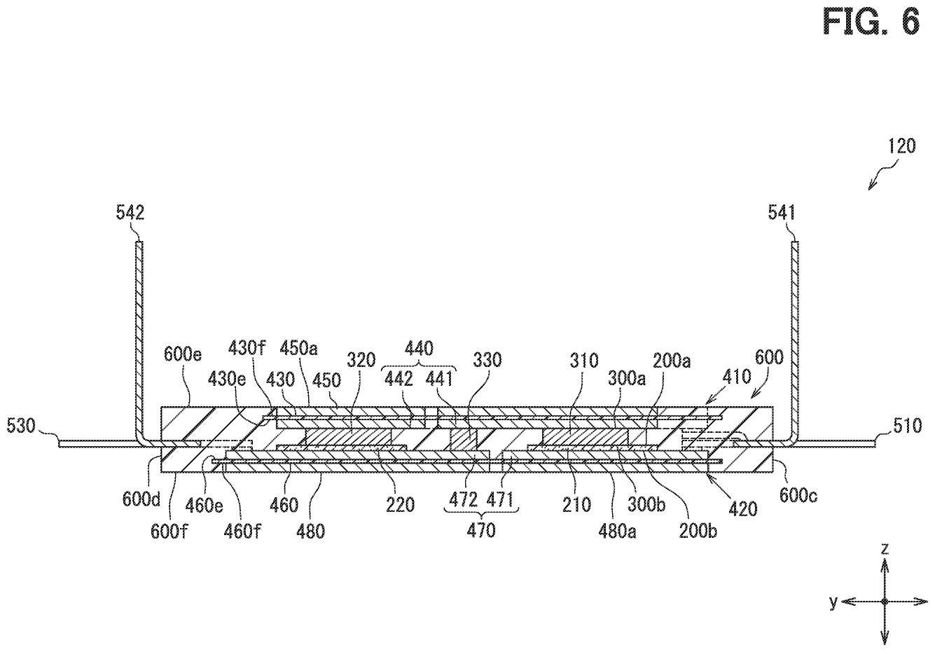

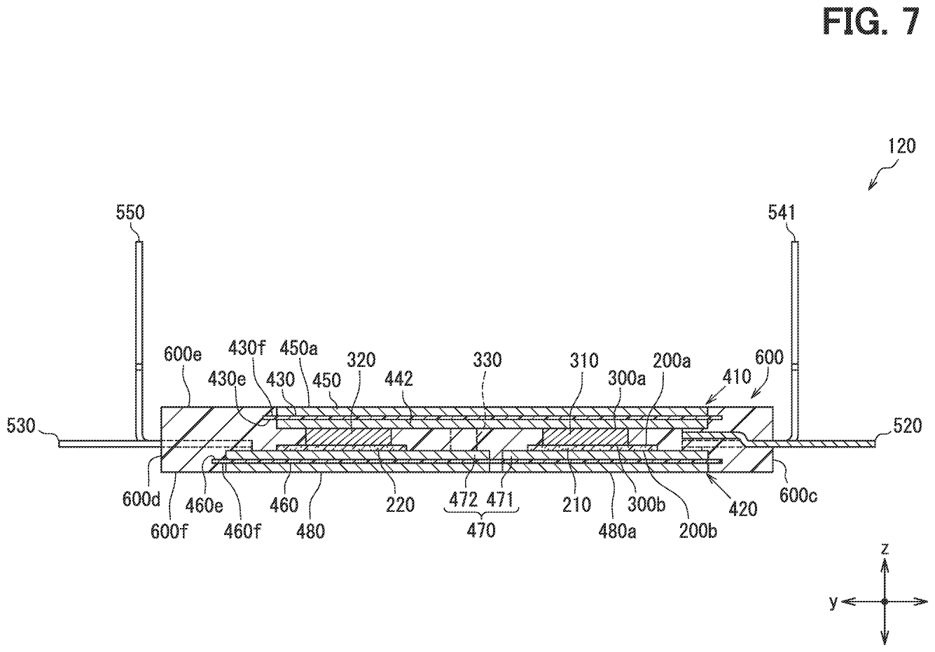

As illustrated in FIGS. 6 and 7, each of the first semiconductor chips 210 and the second semiconductor chips 220 has a flat plate shape which is thin in the z-direction. Each of the first semiconductor chip 210 and the second semiconductor chip 220 has a top surface 200a and a back surface 200b which are aligned in the z-direction. As illustrated in FIG. 2, a source electrode 201 is formed on the top surface 200a. A drain electrode is formed on the back surface 200b, though not shown. Additionally, on the top surface 200a, a gate electrode 203 and a sensor electrode 204 are formed.

The back surface 200b of the first semiconductor chip 210 corresponds to a first main surface. The top surface 200a of the first semiconductor chip 210 corresponds to a second main surface. The back surface 200b of the second semiconductor chip 220 corresponds to a third main surface. The top surface 200a of the second semiconductor chip 220 corresponds to a fourth main surface.

Note that, in the present embodiment, of the first semiconductor chip 210 and the second semiconductor chip 220, only the second semiconductor chip 220 is formed with the sensor electrode 204. The second semiconductor chip 220 is formed with the temperature sensor 160.

Each of the high-side switch 141 and the high-side diode 142 has a vertical structure in which a current flows between the source electrode 201 and the drain electrode of the first semiconductor chip 210. Each of the low-side switch 151 and the low-side diode 152 has a vertical structure in which a current flows between the source electrode 201 and the drain electrode of the second semiconductor chip 220.

The semiconductor chips 200 include the two first semiconductor chips 210 and the two second semiconductor chips 220. To each of the two first semiconductor chips 210 and the two second semiconductor chips 220, the terminal blocks 300 and the conductive plates 400 are electrically connected.

### Terminal Block

The terminal blocks 300 include first terminal blocks 310, second terminal blocks 320, and a third terminal block 330.

Each of the first terminal blocks 310, the second terminal block 320, and the third terminal block 330 has a cuboid shape. A planar shape of each of these three blocks perpendicular to the z-direction is a rectangle. Each of the first terminal blocks 310 and the second terminal blocks 320 has a shape not having an extreme length difference between the x-direction and the y-direction. The third terminal block 330 has a shape which is longer in the x-direction than in the y-direction.

Each the first terminal blocks 310, the second terminal blocks 320, and the third terminal block 330 has a shape has a flat shape which is thin in the z-direction. As illustrated in FIGS. 6 and 7, each of the three blocks has a first end surface 300a and a second end surface 300b which are aligned in the z-direction.

The terminal blocks 300 include the two first terminal blocks 310. The second end surface 300b sides of the two first terminal blocks 310 are individually connected to the two first semiconductor chips 210. The first end surface 300a sides of the two first terminal blocks 310 are connected to a first conductive plate 410 described later.

The terminal blocks 300 include the two second terminal blocks 320. The second end surface 300b sides of the two second terminal blocks 320 are individually connected to the two second semiconductor chips 220. The first end surface 300a sides of the two second terminal blocks 320 are connected to the first conductive plate 410.

The terminal blocks 300 include the one third terminal blocks 330. The second end surface 300b side of the third terminal block 330 is connected to a second conductive plate 420 described later. The first end surface 300a side of the third terminal block 330 is connected to the first conductive plate 410.

### Conductive Plate

The conductive plates 400 include the first conductive plate 410 and the second conductive plate 420.

Each of the first conductive plate 410 and the second conductive plate 420 has a flat shape which is thin in the z-direction. The first conductive plate 410 and the second conductive plate 420 are arranged to be spaced apart from each other in the z-direction. Between these two plates, the semiconductor chips 200 and the terminal blocks 300 are provided.

### First Conductive Plate

As illustrated in FIGS. 6 to 8, the first conductive plate 410 has a first insulating plate 430, a first current-carrying portion 440, and a first heat dissipating portion 450. A material forming the first insulating plate 430 is a resin or ceramic. A material forming the first current-carrying portion 440 and the first heat dissipating portion 450 is a conductive metal material such as copper. In the present embodiment, the first current-carrying portion 440 and the first heat dissipating portion 450 are formed of the same material. Note that the material forming the first heat dissipating portion 450 need not necessarily be conductive.

The first insulating plate 430 has a flat plate shape which is thin in the z-direction. The first insulating plate 430 has a first left surface 430a and a first right surface 430b which are aligned in the x-direction, a first upper surface 430c and a first lower surface 430d which are aligned in the y-direction, and a first inner surface 430e and a first outer surface 430f which are aligned in the z-direction.

The first inner surface 430e is provided with the first current-carrying portion 440. The first outer surface 430f is provided with the first heat dissipating portion 450.

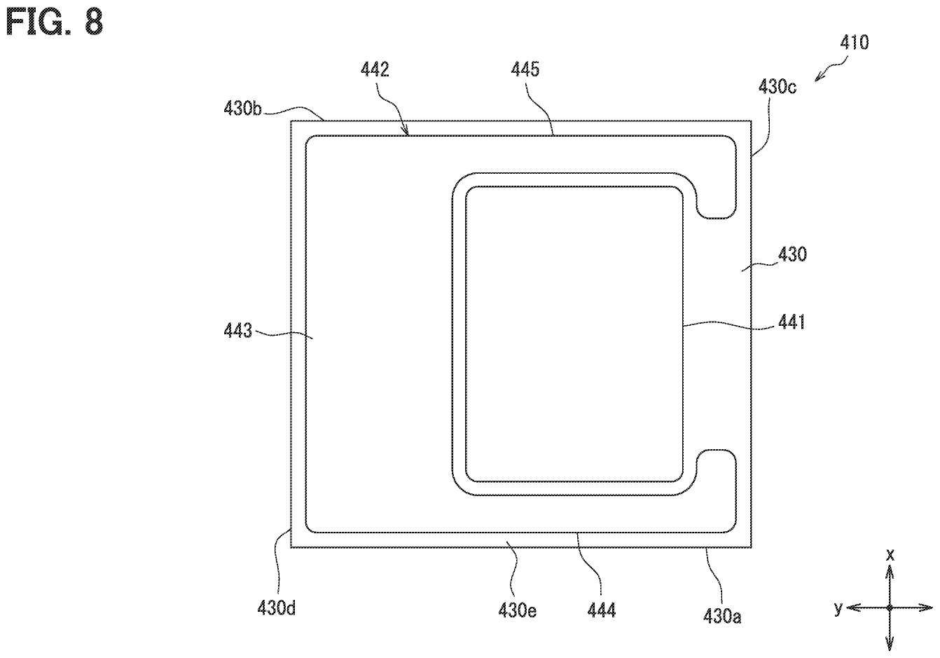

As illustrated in FIG. 8, the first current-carrying portion 440 has a first upper current-carrying portion 441 and a first lower current-carrying portion 442. The first upper current-carrying portion 441 and the first lower current-carrying portion 442 have respective planes perpendicular to the z-direction which have different shapes.

The first upper current-carrying portion 441 has a rectangular shape which is longer in the x-direction than in the y-direction. The first upper current-carrying portion 441 is located on the first upper surface 430c side in the y-direction.

The first lower current-carrying portion 442 has a base portion 443, a first bent portion 444, and a second bent portion 445. The base portion 443 has a rectangular shape which is longer in the x-direction than in the y-direction. The base portion 443 is shorter than the first upper current-carrying portion 441 in the y-direction. The base portion 443 is located on the first lower surface 430d side in the y-direction. The base portion 443 and the first upper current-carrying portion 441 are aligned to be spaced apart from each other in the y-direction.

The first bent portion 444 is integrally connected to the one of the two end portions of the base portion 443 which are aligned in the x-direction to be spaced apart from each other that is located on the first left surface 430a side. The first bent portion 444 extends in the y-direction from the base portion 443 toward the first upper surface 430c side.

The second bent portion 445 is integrally connected to the one of the two end portions of the base portion 443 which are aligned in the x-direction to be spaced apart from each other that is located on the first right surface 430b side. The second bent portion 445 extends in the y-direction from the base portion 443 toward the first upper surface 430c side.

The first bent portion 444 and the second bent portion 445 are aligned to be spaced apart from each other in the x-direction. Between the first bent portion 444 and the second bent portion 445, the first upper current-carrying portion 441 is located.

The first heat dissipating portion 450 is aligned with the first current-carrying portion 440 in the z-direction. The first heat dissipating portion 450 and the first current-carrying portion 440 have respective planes perpendicular to the z-direction which have the same shape. Accordingly, a description thereof is omitted.

### Second Conductive Plate

As illustrated in FIGS. 6, 7 and 9, the second conductive plate 420 has a second insulating plate 460, a second current-carrying portion 470, and a second heat dissipating portion 480. A material forming the second insulating plate 460 is a resin or ceramic. A material forming the second current-carrying portion 470 and the second heat dissipating portion 480 is a conductive metal material such as copper. Note that the material forming the second heat dissipating portion 480 need not necessarily be conductive.

In the present embodiment, the first insulating plate 430 and the second insulating plate 460 are formed of the same material. The first current-carrying portion 440 and the second current-carrying portion 470 are formed of the same material. The first heat dissipating portion 450 and the second heat dissipating portion 480 are formed of the same material.

The second insulating plate 460 has a flat plate shape which is thin in the z-direction. The second insulating plate 460 has a second left surface 460a and a second right surface 460b which are aligned in the x-direction, a second upper surface 460c and a second lower surface 460d which are aligned in the y-direction, and a second inner surface 460e and a second outer surface 460f which are aligned in the z-direction.

The second inner surface 460e is provided with the second current-carrying portion 470. The second outer surface 460f is provided with the second heat dissipating portion 480.

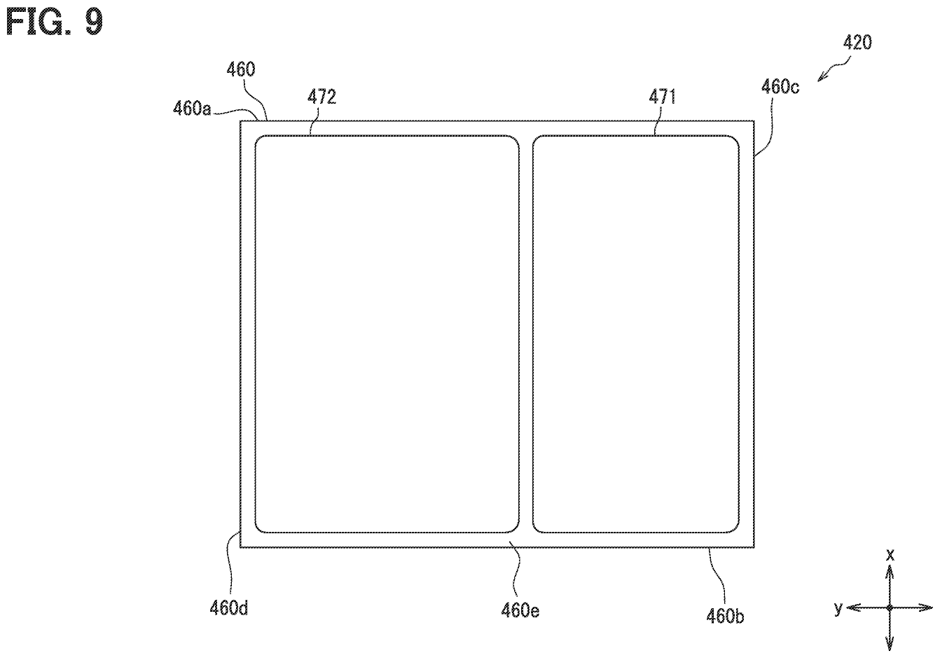

As illustrated in FIG. 9, the second current-carrying portion 470 has a second upper current-carrying portion 471 and a second lower current-carrying portion 472. The second upper current-carrying portion 471 and the second lower current-carrying portion 472 have respective planes perpendicular to the z-direction which have rectangular shapes longer in the x-direction than in the y-direction. The second lower current-carrying portion 472 is longer than the second upper current-carrying portion 471 in the y-direction.

The second upper current-carrying portion 471 is located on the second upper surface 460c side. The second lower current-carrying portion 472 is located on the second lower surface 460d side. The second upper current-carrying portion 471 and the second lower current-carrying portion 472 are aligned to be spaced apart from each other in the y-direction.

The second heat dissipating portion 480 is aligned with the second current-carrying portion 470 in the z-direction. The second heat dissipating portion 480 and the second current-carrying portion 470 have respective planes perpendicular to the z-direction which have the same shape. Accordingly, a description thereof is omitted.

### Connection Terminal

As illustrated in FIG. 2, the connection terminals 500 include drain terminals 510, source terminals 520, midpoint terminals 530, gate terminals 540, and sensor terminals 550. These terminals are produced by performing pressworking on a conductive metal material such as copper. Each of the drain terminals 510 corresponds to a positive electrode terminal. Each of the source terminals 520 corresponds to a negative electrode terminal.

Each of the drain terminals 510, the source terminals 520, and the midpoint terminals 530 extends in the y-direction. However, in the present embodiment, a portion of each of the source terminals 520 is bent. Due to such bending, two end portions of the source terminal 520 located at both ends in an extending direction thereof are at different positions in the z-direction. Note that it is also possible to adopt a configuration in which, conversely, a portion of each of the drain terminals 510 and the midpoint terminals 530 is bent and, due to this, two end portions of each of these terminals located at both ends in an extending direction thereof are at different positions in the z-direction.

Each of the gate terminals 540 and the sensor terminals 550 extends in the y-direction, while being bent to extend in the z-direction.

In the present embodiment, the connection terminals 500 include the two drain terminals 510, the two source terminals 520, and the two midpoint terminals 530. The connection terminals 500 include the four gate terminals 540 and the two sensor terminals 550.

As illustrated in FIG. 2, the plurality of various terminals described heretofore are distributed to and placed on the second upper surface 460c side and the second lower surface 640d side of the second insulating plate 460. On the second upper surface 460c side, the two drain terminals 510, the two source terminals 520, and the two gate terminals 540 are arranged. On the second lower surface 460d side, the two midpoint terminals 530, the two gate terminals 540, and the two sensor terminals 550 are arranged.

Hereinafter, for simplicity of notation, the gate terminals 540 placed on the second upper surface 460c side are referred to as first gate terminals 541. The gate terminals 540 placed on the second lower surface 460d side are referred to as second gate terminals 542. Each of the first gate terminals 541 corresponds to a first control terminal. Each of the second gate terminals 542 corresponds to a second control terminal.

### Distribution and Placement

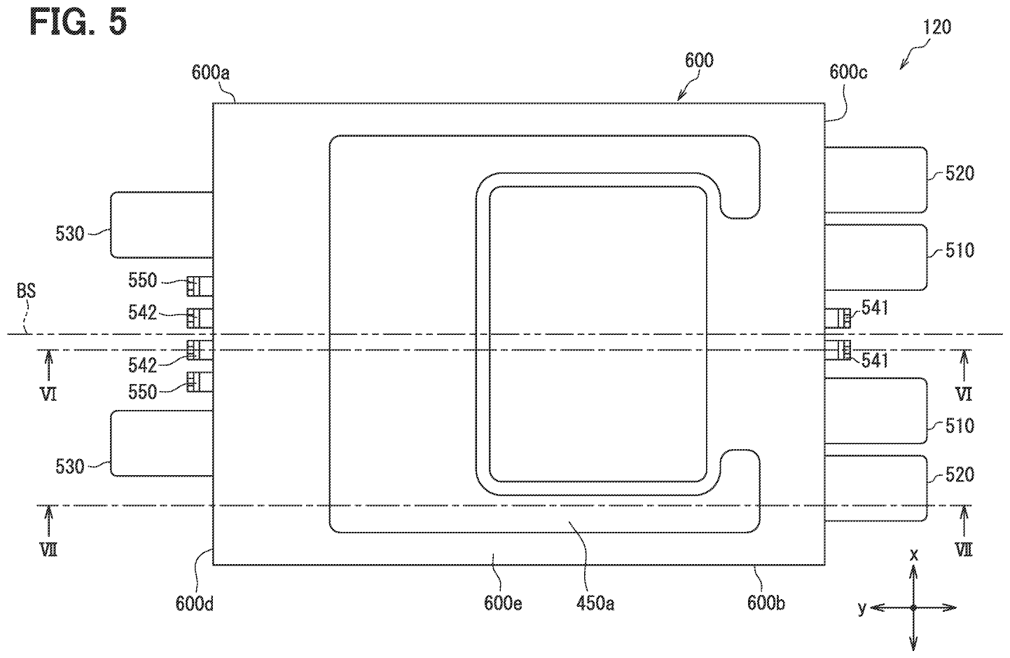

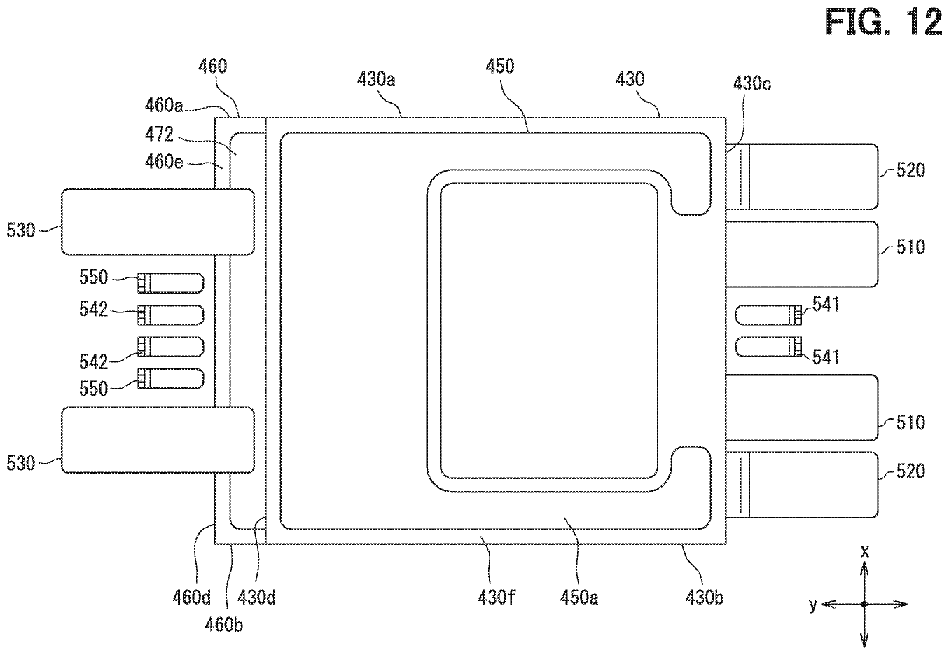

In FIGS. 5 and 12, a reference plane BS passing through a center of the semiconductor module and perpendicular to the x-direction is indicated by a two-dot-dash line. The plurality of various terminals are evenly distributed to and placed in a first distribution space and a second distribution space which are separated via the reference plane BS. The plurality of various terminals are symmetrically placed via the reference plane BS.

On the second upper surface 460c side, the drain terminals 510, the source terminals 520, and the first gate terminals 541 are placed such that the one drain terminal 510, the one source terminal 520, and the one first gate terminal 541 are distributed to each of the first distribution space and the second distribution space. These six terminals are arranged to be spaced apart from each other in the x-direction.

On both end sides of these six terminals arranged to be spaced apart from each other in the x-direction, the source terminals 520 are located. Between these two source terminals 520, the two drain terminals 510 and the two first gate terminals 541 are located. Between the two drain terminals 510, the two first gate terminals 541 are located.

On the second lower surface 460d side, the midpoint terminals 530, the second gate terminals 542, and the sensor terminals 550 are placed such that the one midpoint terminal 530, the one second gate terminal 542, and the one sensor terminal 550 are distributed to each of the first distribution space and the second distribution space. These six terminals are arranged to be spaced apart from each other in the x-direction.

On both end sides of these six terminals arranged to be spaced apart from each other in the x-direction, the midpoint terminals 530 are located. Between these two midpoint terminals 530, the two sensor terminals 550 and the two second gate terminals 542 are located. Between the two sensor terminals 550, the two second gate terminals 542 are located.

Note that it can also be possible to adopt a configuration in which the two second gate terminals 542 arranged to be adjacent to each other in the x-direction and the two sensor terminals 550 arranged to be adjacent to each other in the x-direction are arranged to be adjacent to each other in the x-direction. It is also possible to adopt a configuration in which the second gate terminals 542 and the sensor terminals 550 are alternately arranged to be adjacent to each other in the x-direction.

### Connection Form

As illustrated in FIGS. 6 and 7, in a form in which the first inner surface 430e and the second inner surface 460e face each other in the z-direction, the first conductive plate 410 and the second conductive plate 420 are placed to be spaced apart from each other in the z-direction. Between the first current-carrying portion 440 formed on the first inner surface 430e and the second current-carrying portion 470 formed on the second inner surface 460e, the first semiconductor chip 210 and the second semiconductor chip 220 are provided. In addition, between the two conductive portions, the first terminal blocks 310, the second terminal blocks 320, and the third terminal block 330 are provided.

Moreover, between these two conductive portions, respective end portions of the two drain terminals 510 and the two source terminals 520 are provided. The two first gate terminals 541, the two second gate terminals 542, the two midpoint terminals 530, and the two sensor terminals 550 are provided outside between the two conductive portions.

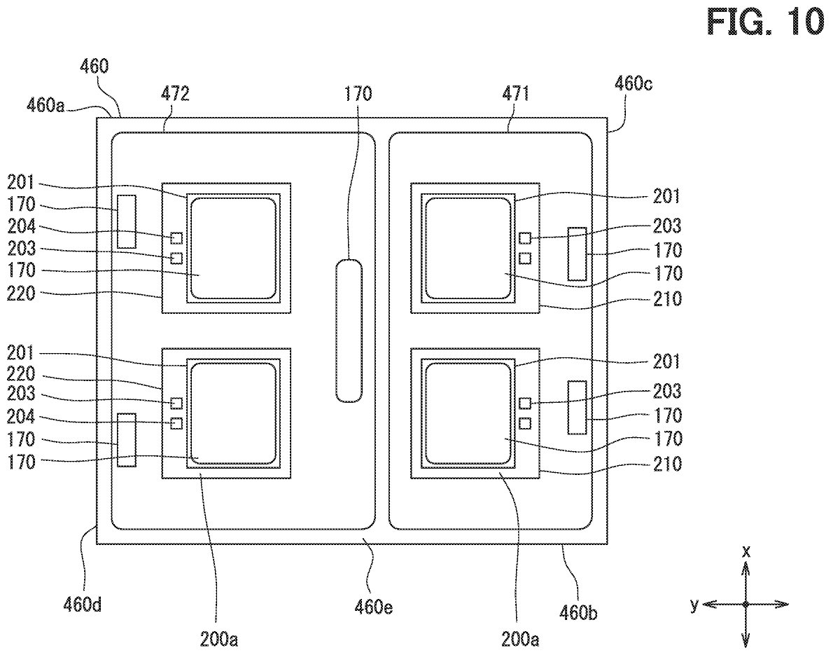

As illustrated in FIG. 10, the second upper current-carrying portion 471 of the second conductive plate 420 is provided with the two first semiconductor chips 210. These two first semiconductor chips 210 are arranged to be spaced apart from each other in the x-direction. The gate electrodes 203 are provided on the second upper surface 460c side in the y-direction.

The drain electrodes of the first semiconductor chips 210 are connected to the second upper current-carrying portion 471 via solders 170 each illustrated in a sheet shape in FIG. 2. Thus, the drains 141a of the high-side switches 141 of the two first semiconductor chips 210 are connected to each other. The second upper current-carrying portion 471 corresponds to a first conductive portion.

The second lower current-carrying portion 472 of the second conductive plate 420 is provided with the two second semiconductor chips 220. These two second semiconductor chips 220 are arranged to be spaced apart from each other in the x-direction. The gate electrodes 203 and the sensor electrodes 204 are provided on the second lower surface 460d side in the y-direction.

In the arrangement described heretofore, the first semiconductor chips 210 and the second semiconductor chips 220 are arranged to be spaced apart from each other in the y-direction. The second semiconductor chip 220 located on the second left surface 460a side in the x-direction and the first semiconductor chip 210 located on the second left surface 460a side in the x-direction are disposed to face each other in the y-direction. The second semiconductor chip 220 located on the second right surface 460b side in the x-direction and the first semiconductor chip 210 located on the second right surface 460b side in the x-direction are disposed to face each other in the y-direction. The first semiconductor chips 210 and the second semiconductor chips 220 which are disposed to face each other in the y-direction are at equal positions in the x-direction.

The drain electrodes of the second semiconductor chips 220 are connected to the second lower current-carrying portion 472 via the solders 170 each illustrated in the sheet shape in FIG. 2. Thus, the respective drains of the low-side switches 151 of the two second semiconductor chips 20 are connected to each other. The second lower current-carrying portion 472 corresponds to a third conductive portion.

As illustrated in FIG. 10, the respective source electrodes 201 of the first semiconductor chips 210 and the second semiconductor chips 220 which are mounted on the second conductive plate 420 are provided with the solders 170. Meanwhile, at two locations on the second upper surface 460c side of the second upper current-carrying portion 471 which are spaced apart from each other in the x-direction, the solders 170 are provided. At two locations on the second upper surface 460c side of the second lower current-carrying portion 472 which are spaced apart from each other in the x-direction, the solders 170 are provided. At one location on the second lower surface 460d side of the second lower current-carrying portion 472, the solder 170 is provided.

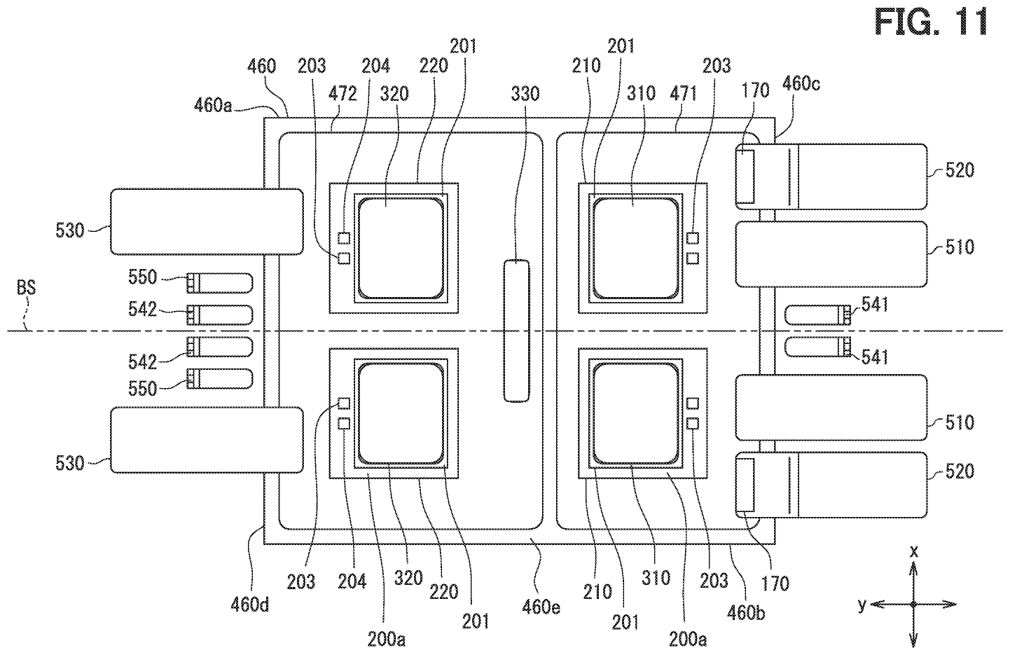

As illustrated in FIG. 11, on the solders 170 provided on the respective source electrodes 201 of the two first semiconductor chips 210, the respective second end surface 300b sides of the two first terminal blocks 310 are individually provided. Thus, the first semiconductor chips 210 and the first terminal blocks 310 are electrically connected.

On the solders 170 provided on the respective source electrodes 201 of the two second semiconductor chips 220, the respective second end surface 300b sides of the two second terminal blocks 320 are individually provided. Thus, the second semiconductor chips 220 and the second terminal blocks 320 are electrically connected.

Meanwhile, on the two solders 170 provided on the second upper surface 460c side of the second upper current-carrying portion 471, respective end portions of the two drain terminals 510 are individually provided. Thus, the two drain terminals 510 are electrically connected to the second upper current-carrying portion 471.

On the solder 170 provided on the second upper surface 460c side of the second lower current-carrying portion 472, the second end surface 300b side of the third terminal block 330 is provided. Thus, the third terminal block 330 is electrically connected to the second lower current-carrying portion 472.

On the two solders 170 provided on the second lower surface 460d side of the second lower current-carrying portion 472, respective end portions of the two midpoint terminals 530 are individually provided. Thus, the two midpoint terminals 530 are electrically connected to the second lower current-carrying portion 472.

As illustrated in FIG. 11, on the second upper surface 460c side, the two first gate terminals 541 are provided. The two first gate terminals 541 have respective end portions individually connected to the respective gate electrodes 203 of the two first semiconductor chips 210 via wires not shown.

On the second lower surface 460d side, the two gate terminals 542 and the two sensor terminals 550 are provided. The two second gate terminals 542 have respective end portions individually connected to the respective gate electrodes 203 of the two second semiconductor chips 220 via wires not shown. The two sensor terminals 550 have respective end portions individually connected to the respective sensor electrodes 204 of the two second semiconductor chips 220 via wires not shown. Alternatively, the respective end portions of the two sensor terminals 550 are connected to the sensor electrode 204 of one of the two second semiconductor chips 220 via wires not shown.

On the first end surface 300a of each of the first terminal blocks 310, the second terminal blocks 320, and the third terminal block 330, the solder 170 is provided. In addition, as illustrated in FIG. 11, on the end portion of each of the source terminals 520, the solder 170 is provided.

As illustrated in FIG. 12, above the second conductive plate 420, the first conductive plate 410 is provided. Thus, the first upper current-carrying portion 441 of the first conductive plate 410 is connected to the solder 170 provided on the first end surface 300a of the first terminal block 310. As a result, the respective sources 141b of the high-side switches 141 of the two first semiconductor chips 210 are connected to each other. Each of the first terminal blocks 310 and the first upper current-carrying portion 441 correspond to the second conductive portion.

Meanwhile, the first upper current-carrying portion 441 is connected to the solder 170 provided on the first end surface 300a of the third terminal block 330. As a result, the first upper current-carrying portion 441 and the second lower current-carrying portion 472 are electrically connected via the third terminal block 330. The third terminal block 330 corresponds to a relay conductive portion.

Furthermore, the base portion 443 of the first lower current-carrying portion 442 is connected to the solder 170 provided on the first end surface 300a of the second terminal block 320. At the same time, the first bent portion 444 and the second bent portion 445 which are extended from the base portion 443 are connected to the respective solders 170 provided on the end portions of the two source terminals 520. As a result, the respective sources 151b of the low-side switches 151 of the two second semiconductor chips 220 are connected. At the same time, the sources 151b of the second semiconductor chips 220 are electrically connected to the source terminals 520. Each of the second terminal blocks 320 and the first lower current-carrying portion 442 correspond to the fourth conductive portion.

### Current-Carrying Path

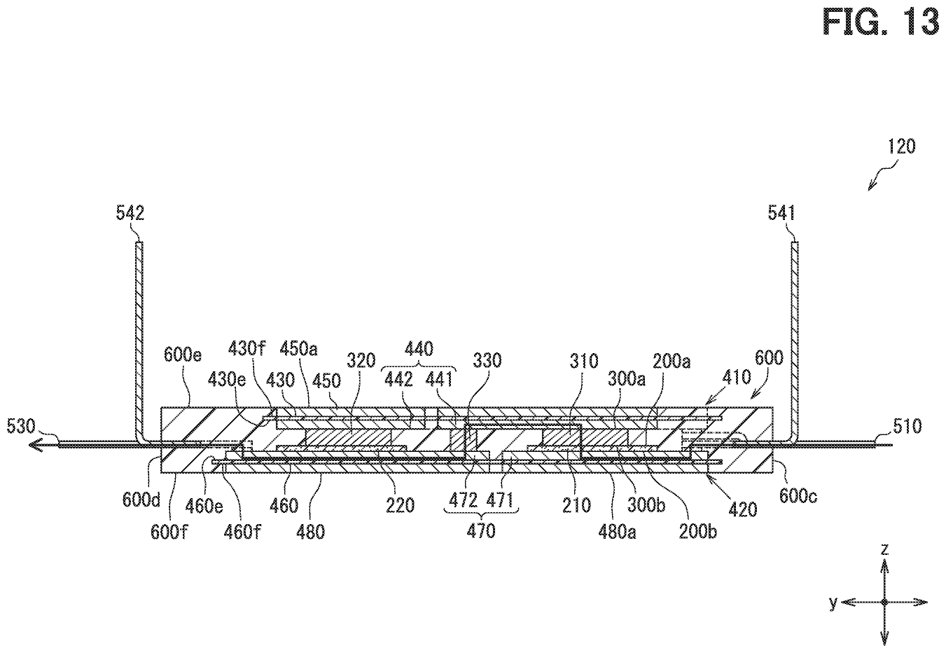

Of the connection structure described heretofore, current-carrying paths indicated by arrows in FIGS. 13 to 16 are formed. The drain terminals 510 and the third terminal block 330 are electrically connected via the second upper current-carrying portion 471, the two first semiconductor chips 210, and the first upper current-carrying portion 441. The third terminal block 330 and the source terminals 520 are electrically connected via the second lower current-carrying portion 472, the two second semiconductor chips 220, the second terminal blocks 320, and the first lower current-carrying portion 442. Additionally, the third terminal block 330 and each of the midpoint terminals 530 are electrically connected via the second lower current-carrying portion 472.

For example, as illustrated in FIG. 13, an energized state and an interrupted state between the high-side switches 141 and the low-side switches 151 are controlled so as to allow currents to flow from the drain terminals 510 toward the midpoint terminals 530. In this case, the currents flow in the y-direction from the drain terminals 510 toward the midpoint terminals 530 via the second upper current-carrying portion 471, the first upper current-carrying portion 441, and the second lower current-carrying portion 472.

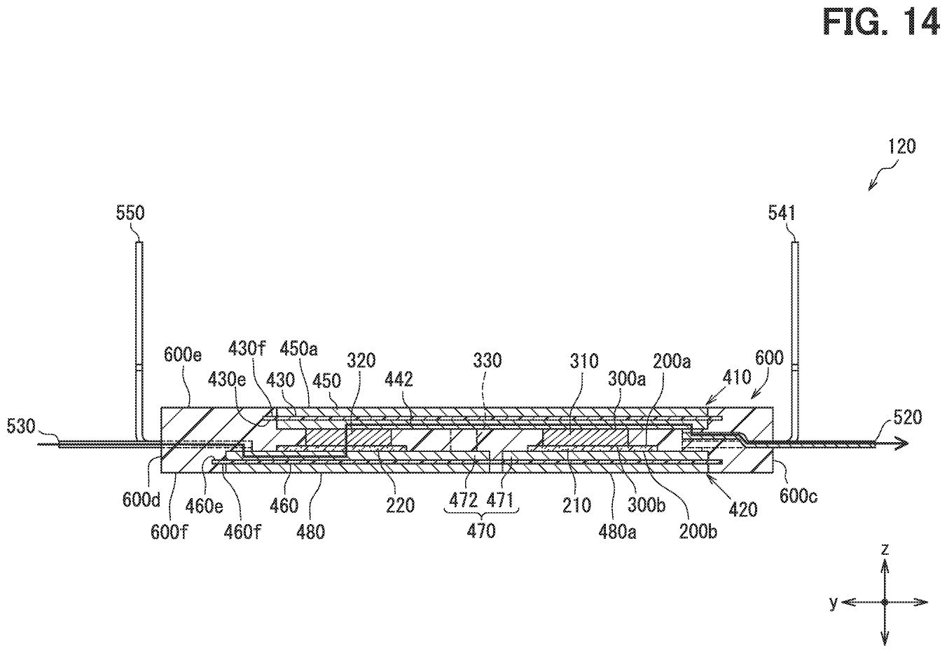

Meanwhile, as illustrated in FIG. 14, an energized state and an interrupted state between the high-side switches 141 and the low-side switches 151 are controlled so as to allow currents to flow from the midpoint terminals 530 toward the source terminals 520. In this case, the currents flow in the y-direction from the midpoint terminals 530 toward the source terminals 520 via the second lower current-carrying portion 472 and the first lower current-carrying portion 442.

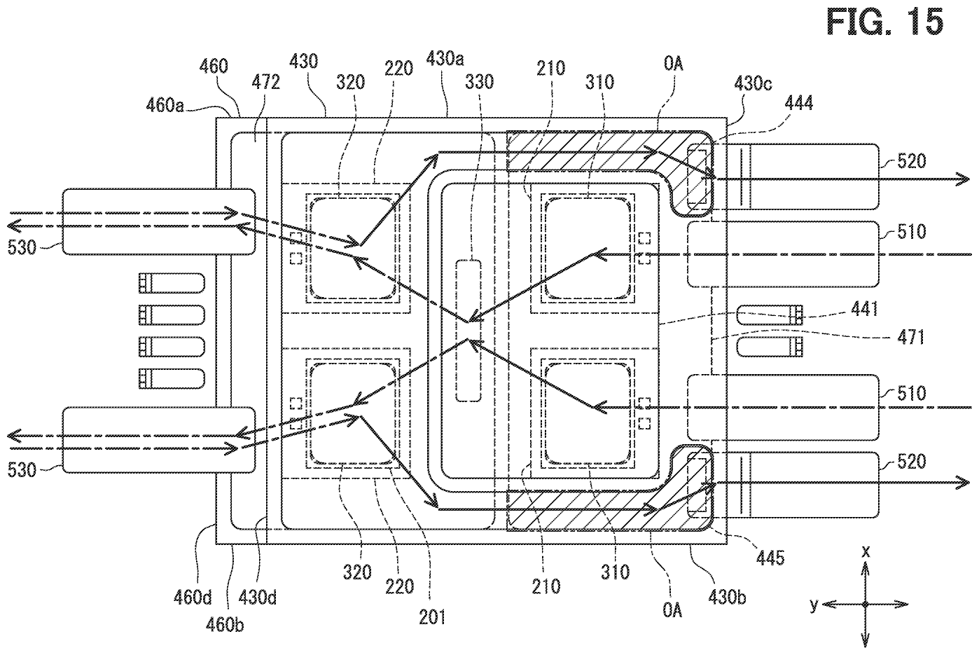

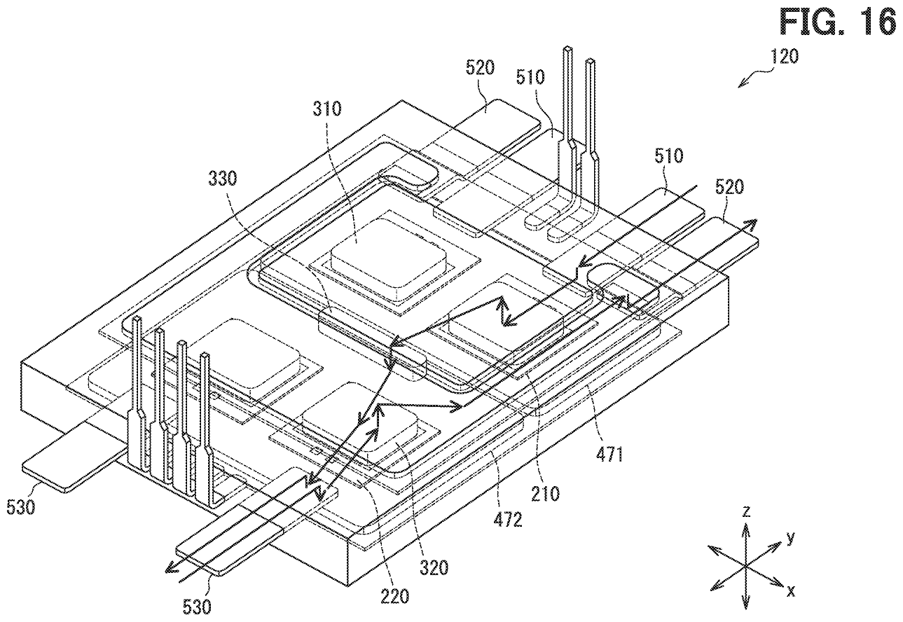

As illustrated in FIGS. 15 and 16, flow directions of the currents flowing from the drain terminals 510 toward the midpoint terminals 530 and flow directions of the currents flowing from the midpoint terminals 530 toward the source terminals 520 are opposite in the y-direction.

The currents flowing from the drain terminals 510 toward the midpoint terminals 530 flow through the first upper current-carrying portion 441. The currents flowing from the midpoint terminals 530 toward the source terminals 520 flow through the first bent portion 444 and the second bent portion 445 of the first lower current-carrying portion 442. As described above, the first upper current-carrying portion 441 is located between the first bent portion 444 and the second bent portion 445 in the x-direction.

Thus, the first upper current-carrying portion 441 and the first bent portion 444 through which the currents flow in the opposite flow directions are arranged adjacent to each other in the x-direction. The first upper current-carrying portion 441 and the second bent portion 445 through which the currents flow in the opposite flow directions are arranged adjacent to each other in the x-direction.

The currents flowing from the drain terminals 510 toward the midpoint terminals 530 individually flow through the two drain terminals 510 and the two first semiconductor chips 210 which are arranged in the x-direction. Current conduction paths of the two currents flowing in the same direction in the y-direction are adjacent to each other in the x-direction.

The currents flowing from the drain terminals 510 toward the midpoint terminals 530 naturally flow in the drain terminals 510. The currents flowing from the midpoint terminals 530 toward the source terminals 520 naturally flow in the source terminals 520. The drain terminals 510 and the source terminals 520 in which the currents flow in the opposite flow directions are arranged adjacent to each other in the x-direction.

Then, the second upper current-carrying portion 471 to which the drain terminals 510 are connected and each of the first bent portion 444 and the second bent portion 445 to which the source terminals 520 are connected are arranged in the z-direction. The second upper current-carrying portion 471 and the first bent portion 444 through which the currents flow in the opposite flow directions are arranged in the z-direction. The second upper current-carrying portion 471 and the second bent portion 445 through which the currents flow in the opposite flow directions are arranged in the z-direction.

Note that, in FIGS. 13 to 16, in order to clearly indicate the current-carrying paths indicated by the arrows, notation of the reference symbols is omitted as appropriate. FIG. 13 corresponds to a cross-sectional view illustrated in FIG. 6. FIG. 14 corresponds to a cross-sectional view illustrated in FIG. 7. In FIG. 15, regions overlapping each other in the upper view illustrated in FIG. 12 are indicated by broken lines. In FIG. 15, illustration of the first heat dissipating portion 450 is omitted. In addition, in FIG. 15, the current-carrying path on the second conductive plate 420 side is indicated by a one-dot-dash line, while the current-carrying path on the first conductive plate 410 side is indicated by a solid line. FIG. 16 illustrates an inner structure of the power card 120 in a see-through state.

### Switch Control

Switch control is not performed so as to allow currents to flow from the drain terminals 510 toward the source terminals 520 between the first semiconductor chips 210 and the second semiconductor chips 220 which have the same phase and are electrically connected in series. The high-side switches 141 and the low-side switches 151 which have the same phase are not simultaneously controlled into the energized state.

Actually, at least either of the high-side switches 141 and the low-side switches 151 is controlled into the interrupted state. By performing such control, as described above, the currents flow from the drain terminals 510 toward the midpoint terminals 530. From the midpoint terminals 530 toward the source terminals 520, the currents flow.

When the high-side switches 141 are controlled into the energized state and the low-side switches 151 are controlled into the interrupted state, currents flow between the drain terminals 510 and the midpoint terminals 530. When potentials at the source terminals 520 become higher than those at the midpoint terminals 530 due to an electromotive force generated in the motor 40 or the like, currents flow from the source terminals 520 toward the midpoint terminals 530 via the low-side diodes 152. When the potentials at the source terminals 520 are lower than those at the midpoint terminals 530, no current flows in the source terminals 520.

When the high-side switches 141 are controlled into the interrupted state and the low-side switches 151 are controlled into the energized state, currents flow between the midpoint terminals 530 and the source terminals 520. When potentials at the midpoint terminals 530 become higher than those at the drain terminals 510 due to an electromotive force or generated in the motor 40 or the like, currents flow from the midpoint terminals 530 toward the drain terminals 510 via the high-side diodes 142. When the midpoint terminals 530 are at the potentials higher than those of the drain terminals 510, no current flows through the drain terminals 510.

When the high-side switches 141 are in the interrupted state and the low-side switches 151 are in the interrupted state, currents flow via at least either of the high-side diodes 142 and the low-side diodes 152. When the high-side diodes 142 are interposed therebetween, currents flow from the midpoint terminals 530 toward the drain electrodes 510. When the low-side diodes 152 are interposed therebetween, currents flow from the source terminals 520 toward the midpoint terminals 530. When both of the high-side diodes 142 and the low-side diode 152 are interposed therebetween, currents flow from the source terminals 520 toward both of the midpoint terminals 530 and the drain terminals 510.

### Overlap of Bent Portions

The second upper current-carrying portion 471 is longer in the x-direction than the first upper current-carrying portion 441. Both end sides of the second upper current-carrying portion 471 in the x-direction no longer overlap the first upper current-carrying portion 441 in the z-direction. The region of the second upper current-carrying portion 471 which does not overlap the first upper current-carrying portion 441 is also the region of the second upper current-carrying portion 471 where the drain terminals 510 and the first semiconductor chips 210 are unconnected.

As described above, the first upper current-carrying portion 441 is located between the first bent portion 444 and the second bent portion 445 in the x-direction. Of the both ends of the second upper current-carrying portion 471 in the x-direction, the end portion on the second left surface 460a side overlaps a portion of the first bent portion 444 in the z-direction. Of the both ends of the second upper current-carrying portion 471 in the x-direction, the end portion on the second right surface 460b side overlaps a portion of the second bent portion 445 in the z-direction. In other words, a part of each of regions where the first bent portion 444 and the second bent portion 445 are projected in the z-direction is located in the region of the second upper current-carrying portion 471 which does not overlap the first upper current-carrying portion 441. In FIG. 15, each of regions where the projected region and the non-overlap area overlap each other in the z-direction is encircled in a two-dot-dash line as an overlap area OA and indicated by oblique hatching. In the overlap area OA, the end portion of the source terminal 520 is located. The end portion of the source terminal 520 is located between the second conductive plate 420 and the first conductive plate 410 in the z-direction.

### Extension of Third Terminal Block

As described above, the third terminal block 330 has the shape elongated in the x-direction. The region where the third terminal block 330 is projected in the y-direction has respective portions which are located in the two first semiconductor chips 210 and the two first terminal blocks 310. The region where the third terminal block 330 is projected in the y-direction has respective portions which are located in the two second semiconductor chips 220 and the two second terminal blocks 320.

To be more locationally specific, a region where a portion of the third terminal block 330 which is connected to the first upper current-carrying portion 441 is projected in the y-direction has respective portions located in respective portions of the two first terminal blocks 310 which are connected to the first upper current-carrying portion 441. A region where a portion of the third terminal block 330 which is connected to the second lower current-carrying portion 472 is projected in the y-direction has respective portions located in respective portions of the drain electrodes of the two second semiconductor chips 220 which are connected to the second lower current-carrying portion 472.

As a result, current-carrying paths between the two first terminal blocks 310 and the one third terminal block 330 in the first upper current-carrying portion 441 are inhibited from being elongated. Current-carrying paths between the one third terminal block 330 and the two second semiconductor chips 220 in the second lower current-carrying portion 472 are inhibited from being elongated.

### Bending of Terminals

As has been described heretofore, the drain terminals 510 are connected to the second upper current-carrying portion 471 of the second conductive plate 420. The midpoint terminals 530 are connected to the second lower current-carrying portion 472 of the second conductive plate 420. The midpoint terminals 530 are connected to the first lower current-carrying portion 442 of the first conductive plate 410.

Since the drain terminals 510 and the midpoint terminals 530 are thus connected to the different conductive plates, respective end portions of the drain terminals 510 and the midpoint terminals 530 which are connected to the second conductive plate 420 are at positions different from positions of end portions of the source terminals 520 which is connected to the first conductive plate 410 in the z-direction.

Meanwhile, as described above, the portion of each of the source terminals 520 is bent. As a result, the end portion of each of the source terminals 520 which is connected to the first conductive plate 410 and a leading end side thereof is at different positions in the z-direction.

As illustrated in FIGS. 6 and 7, the leading end side of the source terminal 520 is located on the second conductive plate 420 side in the z-direction. A separation distance between the leading end side of the source terminal 520 and the first conductive plate 410 in the z-direction is equal to a separation distance between the first conductive plate 410 and the second conductive plate 420 in the z-direction. Consequently, each of the drain terminals 510 and the midpoint terminals 530 and the leading end side of each of the source terminals 520 are at equal positions in the z-direction.

### Coating Resin

The covering resin 600 is made of, e.g., an epoxy-based resin. The covering resin 600 is molded by, e.g., a transfer mold method.

As illustrated in FIGS. 3 to 5, the covering resin 600 has a flat shape which is thin in the z-direction. The covering resin 600 has a cuboid shape having six surfaces. The covering resin 600 has a left surface 600a and a right surface 600b which are arranged to be spaced apart from each other in the x-direction, an upper surface 600c and a lower surface 600d which are arranged to be spaced apart from each other in the y-direction, and a first heat dissipating surface 600e and a second heat dissipating surface 600f which are arranged to be spaced apart from each other in the z-direction.

As descried above, the covering resin 600 covers each of the semiconductor chips 200, the terminal blocks 300, the conductive plates 400, and the connection terminals 500.

As illustrated in FIGS. 6 and 7, the first semiconductor chips 210 and the first terminal blocks 310 are located on the upper surface 600c side in the y-direction. The second semiconductor chips 220 and the second terminal blocks 320 are located on the lower surface 600d side in the y-direction. The third terminal block 330 is located between these in the y-direction. Each of the high-side switches 141 corresponds to a first switch. Each of the low-side switches 151 corresponds to a second switch.

The first conductive plate 410 is located on the first heat dissipating surface 600e side in the z-direction. The second conductive plate 420 is located on the second heat dissipating surface 600f side in the z-direction. With the covering resin 600, the first inner surface 430e side of the first conductive plate 410 is covered. With the covering resin 600, the second inner surface 460e side of the second conductive plate 420 is covered. Each of the first semiconductor chips 210, the second semiconductor chips 220, and the first to third terminal blocks 310 to 330 which are provided between the first heat dissipating surface 600e and the second heat dissipating surface 600f is covered with the covering resin 600.

With the covering resin 600, the first outer surface 430f side of the first conductive plate 410 is also covered. However, the first heat dissipating portion 450 provided on the first outer surface 430f has a portion exposed from the covering resin 600. A surface (first exposed surface 450a) of the first heat dissipating portion 450 exposed from the covering resin 600 is flush with the first heat dissipating surface 600e. Note that the first exposed surface 450a need not necessarily be flush with the first heat dissipating surface 600e.

With the covering resin 600, the second outer surface side 460f of the second conductive plate 420 is also covered. However, the second heat dissipating portion 480 provided on the second outer surface 460f has a portion exposed from the covering resin 600. A surface (second exposed surface 480a) of the second heat dissipating portion 480 exposed from the covering resin 600 is flush with the second heat dissipating surface 600f. Note that the second exposed surface 480a need not necessarily be flush with the second heat dissipating surface 600f.

The covering resin 600 covers respective portions of the drain terminals 510, the source terminals 520, and the midpoint terminals 530 which are connected to the conductive plates 400. The covering resin 600 covers respective portions of the sensor terminals 550, the first gate terminal 541, and the second gate terminal 542 which are connected to the semiconductor chips 200. These various terminals have respective leading end sides exposed from the covering resin 600.

The drain terminals 510, the source terminals 520, and the first fate terminals 541 have the respective leading end sides exposed from the upper surface 600c. The leading end sides of the drain terminal 510 and the source terminals 520 extend in the y-direction, while being spaced apart from the upper surface 600c. The leading end side of each of the first gate terminals 541 extends in the y-direction, while being spaced apart from the upper surface 600c, to be bent and extend from the second heat dissipating surface 600f toward the first heat dissipating surface 600e in the z-direction. As illustrated in FIG. 4, the bent portion of the first gate terminal 541 is located on the upper surface 600c side of respective most leading end portions of the drain terminals 510 and the source terminals 520 in the y-direction.

The midpoint terminals 530, the second gate terminals 542, and the sensor terminals 550 have respective leading end sides exposed from the lower surface 600d. The respective leading end sides of the midpoint terminals 530 extend in the y-direction, while being spaced apart from the lower surface 600d. The respective leading end sides of the second gate terminals 542 and the sensor terminals 550 extend in the y-direction, while being spaced apart from the lower surface 600d, to be bent and extend from the second heat dissipating surface 600f toward the first heat dissipating surface 600e in the z-direction. Respective bent portions of the second gate terminals 542 and the sensor terminals 550 are located on the lower surface 600d side of respective most leading end portions of the midpoint terminals 530 and the sensor terminals 550 in the y-direction.

### Cooler

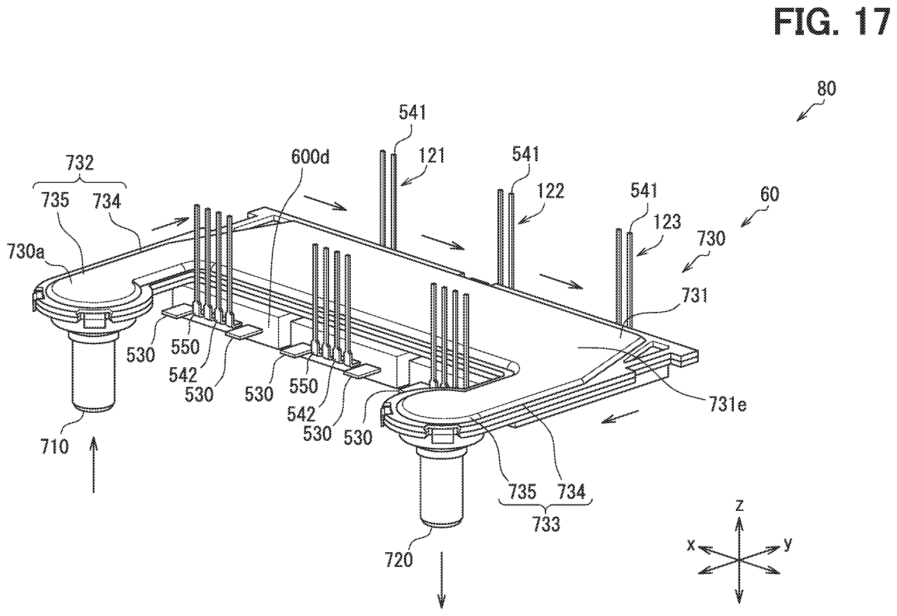

The power conversion unit 30 has, in addition to the power conversion device 50, a cooler 60 illustrated in FIGS. 17 to 19. The cooler 60 has a function of cooling each of the U-phase to W-phase semiconductor modules 121 to 123 described heretofore.

As illustrated in FIG. 17, the cooler 60 has a supply pipe 710, an exhaust pipe 720, and a cooling unit 730. The supply pipe 710 and the exhaust pipe 720 are connected via the cooling unit 730. To the supply pipe 710, a refrigerant is supplied. The refrigerant flows from the supply pipe 710 to the exhaust pipe 720 via an inner space of the cooling unit 730.

Each of the supply pipe 710 and the exhaust pipe 720 extends in the z-direction. The supply pipe 710 and the exhaust pipe 720 are spaced apart from each other in the x-direction. The cooling unit 730 has a plat shape which is thin in the z-direction.

### Cooling Unit

In more detail, the cooling unit 730 has a facing portion 731, a first arm portion 732, and a second arm portion 733. To the facing portion 731, each of the first arm portion 732 and the second arm portion 733 is connected. These three components have respective hollows (inner spaces) in which the refrigerant flows. The respective hollows of these three components communicate with each other.

To the first arm portion 732, the supply pipe 710 is connected. To the second arm portion 733, the exhaust pipe 720 is connected. Due to such a configuration, the refrigerant supplied from the supply pipe 710 flows into the facing portion 731 via the first arm portion 732. The refrigerant that has flown into the facing portion 731 flows into the exhaust pipe 720 via the second arm portion 733. A direction in which the refrigerant flows is indicated by solid-line arrows in FIG. 17.

The facing portion 731 has a first side surface 731a and a second side surface 731b which are arranged to be spaced apart from each other in the x-direction, a third side surface 731c and a fourth side surface 731d which are arranged to be spaced apart from each other in the y-direction, and an outer surface 731e and an inner surface 731f which are arranged to be spaced apart from each other in the z-direction.

Each of the first arm portion 732 and the second arm portion 733 is connected to the fourth side surface 731d of the facing portion 731. The first arm portion 732 and the second arm portion 733 are spaced apart from each other in the x-direction. In the x-direction, the first arm portion 732 is located on the first side surface 731a side of the second arm portion 733. The second arm portion 733 is located on the second side surface 731b side of the first arm portion 732.

Each of the first arm portion 732 and the second arm portion 733 extends in the y-direction, while being spaced apart from the fourth side surface 731d. The first arm portion 732 and the second arm portion 733 respectively have an upper outer surface 730a and a lower inner surface 730b which are arranged in the z-direction. To the leading-end-side lower inner surface 730b of the first arm portion 732, the supply pipe 710 is connected. To the leading-end-side lower inner surface 730b of the second arm portion 733, the exhaust pipe 720 is connected.

Hereinafter, for simplicity of notation, the facing portion 731 side of each of the first arm portion 732 and the second arm portion 733 is shown as an extended portion 734. The leading end side of each of the first arm portion 732 and the second arm portion 733 is shown as a pipe connection portion 735.

### Locations of Supply Pipe and Exhaust Pipe in X-Direction

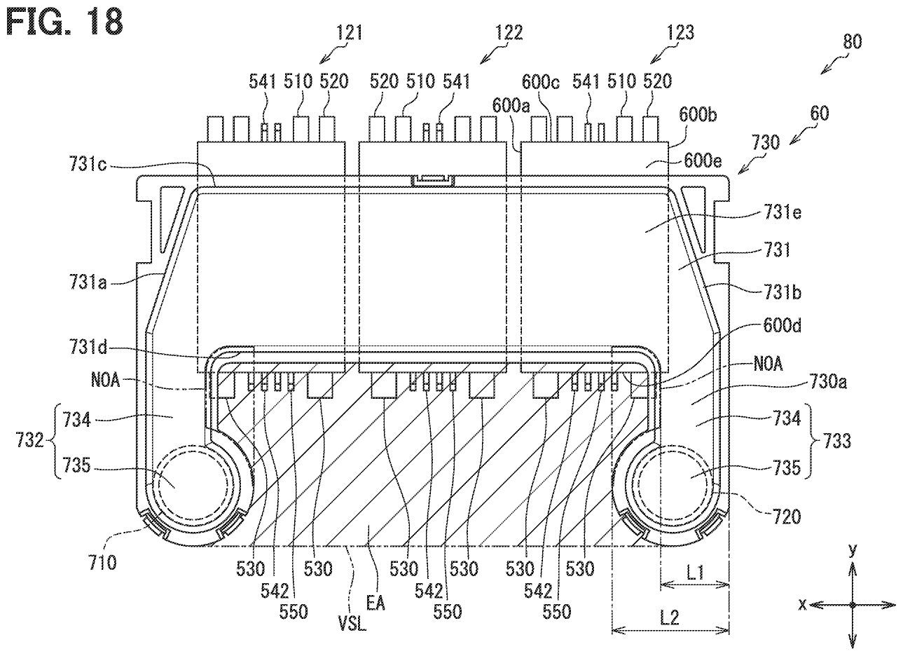

For example, as illustrated in FIG. 18, a length of each of the extended portions 734 in the x-direction is L1 and uniform. Meanwhile, a length of each of the pipe connection portions 735 in the x-direction is non-uniform. Respective portions of the pipe connection portions 735 which are connected to the supply pipe 710 and the exhaust pipe 720 have circular shapes in a plane perpendicular to the z-direction. In FIG. 18, the supply pipe 710 and the exhaust pipe 720 are indicated by broken lines.

The supply pipe 710 and the exhaust pipe 720 have respective outer diameters longer than the lengths of the extended portions 734 in the x-direction. Accordingly, a maximum length L2 of each of the pipe connection portions 735 in the x-direction is larger than a maximum length L1 of each of the extended portions 734 in the x-direction.

Due to such a magnitude relationship between the lengths in the x-direction and the respective shapes of the extended portions 734 and the pipe connection portions 735, the extended portions 734 are entirely located in portions of regions where the pipe connection portions 735 are projected in the y-direction. In the present embodiment, in non-overlap areas NOA of the regions where the pipe connection portions 735 are projected in the y-direction which do not overlap the extended portions 734, the fourth side surface 731d is located. In FIG. 18, regions of the non-overlap areas NOA which are between the pipe connection portions 735 and the fourth side surface 731d are encircled in and indicated by two-dot-dash lines.

As is obvious, the fourth side surface 731d on which the non-overlap areas NOA of the pipe connection portions 735 are located is located between the first side surface 731a and the second side surface 731b in the x-direction. The extended portions 734 connected to the pipe connection portions 735 extend from the fourth side surface 731d in the y-direction. Due to such a configuration, positions of the pipe connection portions 735 of the first arm portion 732 and the second arm portion 733 in the x-direction are between the first side surface 731a and the second side surface 731b.

### Enclosed Area

Due to the configuration described heretofore, as illustrated in FIG. 18, an enclosed area EA is defined by the facing portion 731, the first arm portion 732, and the second arm portion 733 each included in the cooling unit 730.

The enclosed area EA is defined in the y-direction by the fourth side surface 731d and by a virtual straight line VSL connecting a leading end of the first arm portion 732 and a leading end of the second arm portion 733. The enclosed area EA is defined in the x-direction by an inner surface of the first arm portion 732 on the second arm portion 733 side and by an inner surface of the second arm portion 733 on the first arm portion 732 side. In FIG. 18, the enclosed area EA is indicated by oblique-line hatching. The virtual straight line VSL is indicated by a two-dot-dash line.

### Power Module

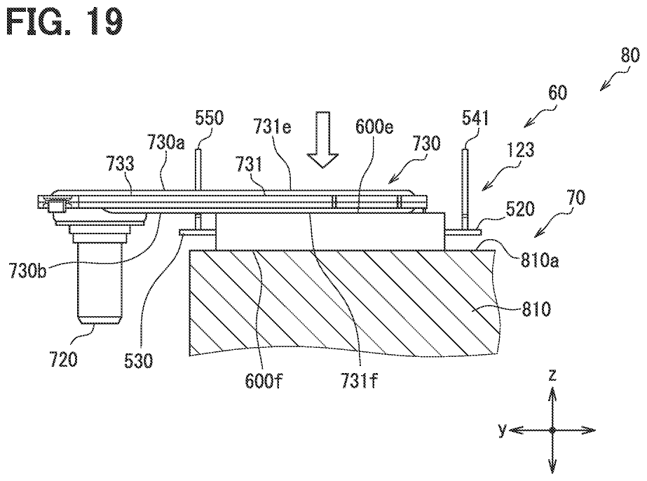

The cooler 60 is contained together with the power conversion device 50 in a housing 70 produced by, e.g., aluminum die-casting. As illustrated in FIG. 19, the facing portion 731 of the cooling unit 730 is disposed to face a wall portion 810 of the housing 70 to be spaced apart from therefrom in the z-direction.

Between the inner surface 731f of the facing portion 731 and a mounting surface 810a of the wall portion 810, a space is configured (defined). In the space, the U-phase semiconductor module 121, the V-phase semiconductor module 122, and the W-phase semiconductor module 123 are provided. The covering resin 600 of the plurality of semiconductor modules is provided between the facing portion 731 and the wall portion 810. The plurality of semiconductor modules and the cooler 60 are included in the power module 80.

The U-phase semiconductor module 121, the V-phase semiconductor module 122, and the W-phase semiconductor module 123 are arranged in this order in the x-direction from the first side surface 731a side toward the second side surface 731b side.

To the facing portion 731 of the cooling unit 730, a biasing force indicated by an open arrow in FIG. 19 is given. By this biasing force, the plurality of semiconductor modules are held between the facing portion 731 and the wall portion 810.

Between the inner surface 731f of the facing portion 731 and each of the first exposed surface 450a and the first heat dissipating surface 600e of the semiconductor module, a heat transfer member such as grease is provided, though not shown. Likewise, between each of the second exposed surface 480a and the second heat dissipating surface 600f of the semiconductor module and the mounting surface 810a of the wall portion 810, a heat transfer member such as grease is provided. Such a configuration allows the semiconductor module to positively transfer heat to the cooler 60 and to the wall portion 810. Note that each of the first heat dissipating surface 600e and the second heat dissipating surface 600f need not necessarily be provided with the heat transfer member described above. In addition, there is originally no need to provide the heat transfer member.

Due to the connection configuration described heretofore, each of the U-phase semiconductor module 121, the V-phase semiconductor module 122, and the W-phase semiconductor module 123 performs heat exchange with the refrigerant mainly flowing inside the facing portion 731 in the x-direction.

Note that the wall portion 810 on which the semiconductor modules are provided need not necessarily be a part of the housing 70. The semiconductor modules may also be provided on the wall portion 810 separate from the housing 70. A flow path along which the refrigerant flows may also be configured inside the wall portion 810.

As illustrated in FIGS. 17 and 18, the upper surface 600c side and the lower surface 600d side of the covering resin 600 are provided outside the void. Consequently, the respective leading end sides of the drain terminals 510, the source terminals 520, and the first gate terminals 541 which are exposed from the upper surface 600c are provided outside the void. The respective leading end sides of the midpoint terminals 530, the second gate terminals 542, and the sensor terminals 550 which are exposed from the lower surface 600d are provided outside the void. The leading ends of the plurality of terminals protruding from the lower surface 600d are aligned with the enclosed area EA described above in the z-direction.

As illustrated in FIG. 18, the first gate terminals 541 extend in the y-direction so as to be spaced apart from the upper surface 600c, are subsequently bent, and extend in the z-direction so as to be spaced apart from the wall portion 810. The second gate terminals 542 and the sensor terminals 550 extend in the y-direction so as to be spaced apart from the lower surface 600d, are subsequently bent, and extend in the z-direction so as to be spaced from the wall portion 810. The leading end of each of the second gate terminals 542 and the sensor terminals 550 has a portion provided in the enclosed area EA.

The control substrate 130 is provided above the plurality of semiconductor modules in the z-direction. Between the control substrate 130 and the plurality of semiconductor modules, the cooling unit 730 is located. In the control substrate 130, a plurality of through holes are formed to extend therethrough in the z-direction. Through the plurality of through holes, the first gate terminals 541, the second gate terminal 542, and the sensor terminals 550 are inserted. These terminals are connected to the control substrate 130 via solder or the like.

### P Bus Bar and N Bus Bar

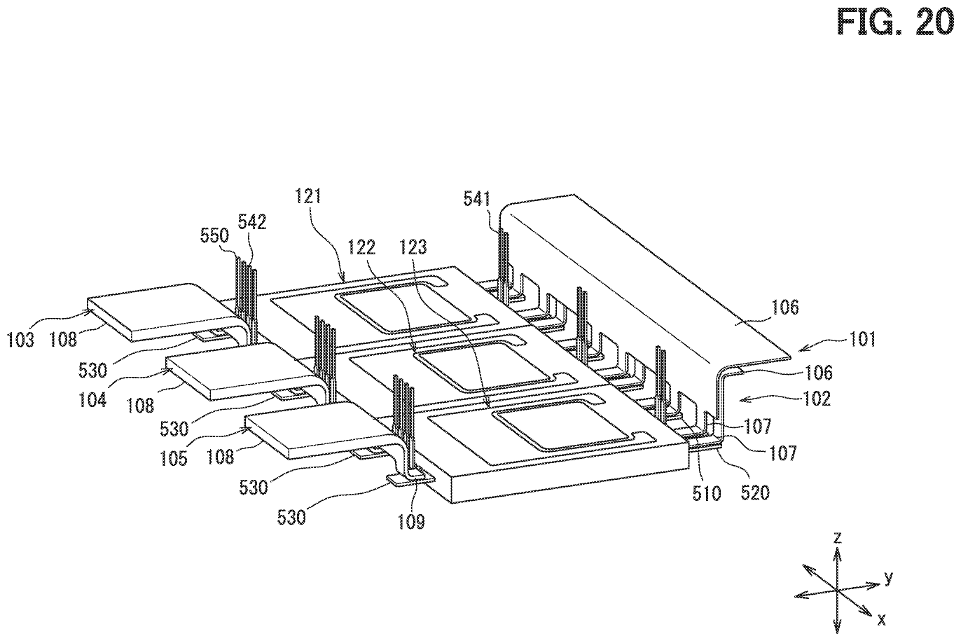

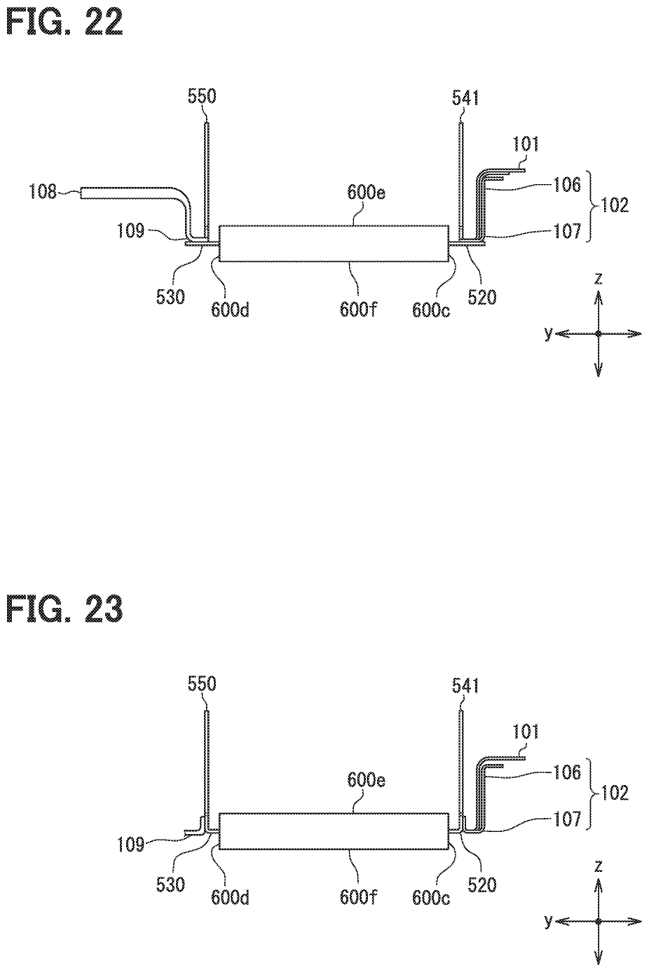

As described above, to the drain terminals 510, the P bus bar 101 is connected. To the source terminals 520, the N bus bar 102 is connected. The P bus bar 101 and the N bus bar 102 are fabricated by press-working a flat plate of copper or the like. As illustrated in FIGS. 20 to 22, each of the P bus bar 101 and the N bus bar 102 has a main plate 106 and leg portions 107.

The main plate 106 has a shape which is exclusively long in the x-direction. The main plate 106 extends in the y-direction to be subsequently bent and extend in the z-direction. The main plate 106 is bent into a letter-L shape in a plane perpendicular to the x-direction. To a portion of the main plate 106 which extends in the y-direction, an electrode of the smoothing capacitor 110 is connected. To a portion of the main plate 106 which extends in the z-direction, the plurality of leg portions 107 are integrally connected.

Each of the plurality of leg portions 107 extends from the main plate 106 in the z-direction to be subsequently bent and extend in the y-direction, while being spaced apart from the main plate 106. The leg portion 107 is bent into a letter-L shape in a plane perpendicular to the x-direction. The plurality of leg portions 107 are arranged to be spaced apart from each other in the x-direction. In the present embodiment, the six leg portions 107 are integrally connected to the main plate 106.

As illustrated in FIGS. 20 to 22, the main plate 106 of the P bus bar 101 and the main plate 106 of the N bus bar 102 are disposed to be superposed in each of the z-direction and the y-direction. Between these two main plates 106, a thin insulating sheet is interposed. Each of the P bus bar 101 and the N bus bar 102 is aligned with the U-phase to W-phase semiconductor modules 121 to 123 in the y-direction.

In a state where the two main plates 106 are stacked, the leg portions 107 of the P bus bar 101 and the leg portions 107 of the N bus bar 102 are arranged to be spaced apart from each other in the x-direction. Between the two leg portions 107 of the N bus bar 102, the two leg portions 107 of the P bus bar 101 are located. The four leg portions 107 arranged in this mode make a set, and three sets of the four leg portions 107 are made. The three sets of the four leg portions 107 are arranged in the x-direction.

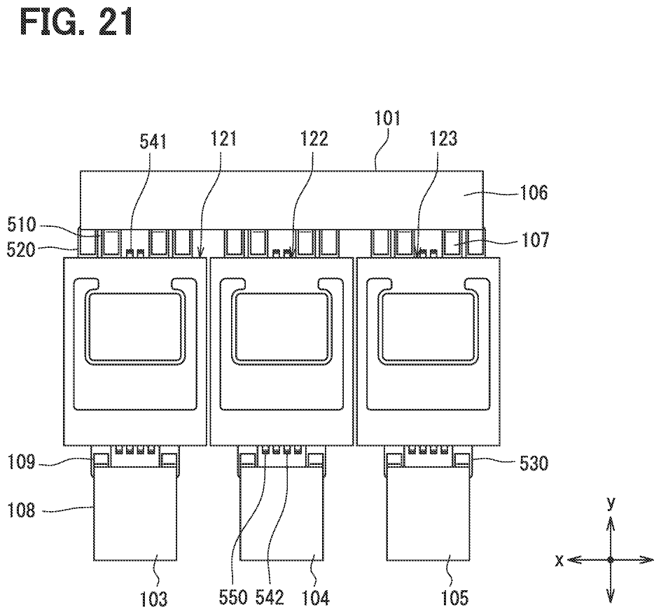

As illustrated in FIG. 21, portions of the leg portions 107 of the P bus bar 101 which extend in the y-direction are disposed to face the drain terminals 510 in the z-direction. In this facing arrangement state, the leg portions 107 of the P bus bar 101 and the drain terminals 510 are joined together.

Portions of the leg portions 107 of the N bus bar 102 which extend in the y-direction are disposed to face the source terminals 520 in the z-direction. In this facing arrangement state, the leg portions 107 of the N bus bar 102 and the source terminals 520 are joined together.

As described above, each of the first gate terminals 541 extends in the y-direction from the upper surface 600c of the covering resin 600 to be subsequently bent and extend in the z-direction. The bent portion of each of the first gate terminals 541 is located on the upper surface 600c side of the most leading end portion of each of the drain terminals 510 and the source terminals 520 in the y-direction.

The portion of each of the first gate terminals 541 which extends in the z-direction is aligned with the respective main plates 106 of the P bus bar 101 and the N bus bar 102 to be spaced apart from each other in the y-direction. Thus, interference between the first gate terminals 541 and the main plates 106 is avoided. A separation distance between each of the first gate terminals 541 and each of the main plates 106 is determined so as to ensure insulation therebetween.

Note that, as illustrated in FIG. 23, it may also be possible that each of the leg portions 107 extends from each of the main plate 106 in the z-direction to be subsequently bent, extends in the y-direction so as to be spaced apart from the main plate 106, and is subsequently bent again to extend in the z-direction. It may also be possible that the drain terminals 510 and the source terminals 520 extend from the upper surface 600c in the y-direction to be subsequently bent and extend in the z-direction. The portions of the leg portions 107 which extend again from the bent portions thereof in the z-direction and the respective portions of the drain terminals 510 and the source terminals 520 which extend in the z-direction may also be joined together, while being disposed to face each other in the y-direction.

### Phase Bus Bar

As described above, to the respective midpoint terminals 530 of the U-phase semiconductor module 121, the V-phase semiconductor module 122, and the W-phase semiconductor module 123, the U-phase bus bar 103, the V-phase bus bar 104, and the W-phase bus bar 105 are individually connected. These 3-phase bus bars are each fabricated by pressworking a flat plate of copper or the like. As illustrated in FIGS. 20 to 22, each of the U-phase to W-phase bus bars 103 to 105 has an elongated plate 108 and connection end portions 109.

Each of the elongated plates 108 has a shape exclusively elongated in the y-direction. The elongated plate 108 extends in the y-direction to be subsequently bent and extend in the z-direction. The elongated plate 108 is bent into a letter-L shape in a plane perpendicular to the x-direction. To the portion of the elongated plate 108 which extends in the y-direction, a stator coil of the motor 40 is connected. To the portion of the elongated plate 108 which extends in the z-direction, the plurality of connection end portions 109 are integrally connected.

Each of the plurality of connection end portions 109 extends from the elongated plate 108 in the z-direction to be subsequently bent and extend in the y-direction, while being spaced apart from the elongated plate 108. The connection end portion 109 is bent into a letter-L shape in a plane perpendicular to the x-direction. The plurality of connection end portions 109 are arranged to be spaced apart from each other in the x-direction. In the present embodiment, the two connection end portions 109 are integrally connected to each of the elongated plates 108.

As illustrated in FIGS. 20 to 22, the respective elongated plates 108 of the U-phase to W-phase bus bars 103 to 105 are arranged to be spaced apart from each other in the x-direction. The U-phase bus bar 103 is aligned with the U-phase semiconductor module 121 in the y-direction. The V-phase bus bar 104 is aligned with the V-phase semiconductor module 122 in the y-direction. The W-phase bus bar 105 is aligned with the W-phase semiconductor module 123 in the y-direction.

The two connection end portions 109 connected to each of the three elongated plates 108 are also arranged to be spaced apart from each other in the x-direction. The total of six connection end portions 109 are arranged to be spaced apart from each other in the x-direction.

As illustrated in FIG. 21, a portion of one of the two connection end portions 109 connected to the elongated plate 108 which extends in the y-direction is disposed to face one of the two midpoint terminals 530 in the z-direction. A portion of another of the two connection end portions 109 connected to the elongated plate 108 which extends in the y-direction is disposed to face another of the two midpoint terminals 530 in the z-direction. In this facing arrangement state, the two connection end portions 109 and the two midpoint terminals 530 are individually joined together.

In a state where the connection end portions 109 are thus joined to the midpoint terminals 530, each of the U-phase to W-phase bus bars 103 to 105 has a portion provided in the enclosed area EA described above.

As described above, the second gate terminals 542 and the sensor terminals 550 extend from the lower surface 600d of the covering resin 600 in the y-direction to be subsequently bent and extend in the z-direction. The respective bent portions of the second gate terminals 542 and the sensor terminals 550 are located on the lower surface 600d side of the most leading end portions of the midpoint terminals 530 in the y-direction.

The respective portions of the second gate terminals 542 and the sensor terminals 550 which extend in the z-direction are aligned with the elongated plate 108 to be spaced apart therefrom in the y-direction. This avoids interference between each of the second gate terminals 542 and the sensor terminals 550 and the elongated plate 108. A separation distance between each of the second gate terminals 542 and the sensor terminals 550 and the elongated plate 108 is determined so as to ensure insulation therebetween.

Note that, as illustrated in FIG. 23, it may also be possible that each of the connection end portions 109 extends from the elongated plate 108 in the z-direction to be subsequently bent, extends in the y-direction, while being spaced apart from the elongated plate 108, and is subsequently bent again to extend in the z-direction. It may also be possible that the midpoint terminals 530 extend from the lower surface 600d in the y-direction to be subsequently bent and extend in the z-direction. The portions of the connection end portions 109 which extend again in the z-direction from the bent portions thereof and the portions of the midpoint terminals 530 which extend in the z-direction may also be joined together, while being disposed to face each other in the y-direction.

### Function Effect

As has been described heretofore, each of the U-phase to W-phase semiconductor modules 121 to 123 has the first semiconductor chip 210 and the second semiconductor chip 220 which are arranged to be spaced apart from each other in the y-direction. The first semiconductor chip 210 and the second semiconductor chip 220 which are arranged to be spaced apart from each other in the y-direction perform heat exchange with the refrigerant mainly flowing in the x-direction inside the facing portion 731.

A direction in which the first semiconductor chip 210 formed with the high-side switches 141 and the second semiconductor chip 220 formed with the low-side switches 151 are thus arranged crosses the flowing direction of the refrigerant flowing inside the facing portion 731 that cools these semiconductor chips. The direction in which the high-side switches 141 and the low-side switches 151 which are electrically connected are arranged and the flowing direction of the refrigerant that cools these switches cross each other.

This inhibits differences in heat exchange amount from being produced between the high-side switches 141 and the refrigerant flowing in the facing portion 731 and between the low-side switches 151 and the refrigerant flowing in the facing portion 731. Each of the first semiconductor chip 210 and the second semiconductor chip 220 which are protectively covered with the covering resin 600, while being arranged to be spaced apart from each other in the y-direction is inhibited from having a difference in heat exchange amount with the refrigerant flowing in the facing portion 731.

The two drain terminals 510 are distributed to a first distribution space and a second distribution space, and the two source terminals 520 are distributed to the first distribution space and the second distribution space. The first gate terminals 541 are located between the drain terminal 510 and the source terminal 520 which are provided in the first distribution space and between the drain terminal 510 and the source terminal 520 which are provided in the second distribution space.

As a result, electromagnetic noise generated from the drain terminal 510 located in the first distribution space and electromagnetic noise generated from the drain terminal 510 located in the second distribution space are likely to be cancelled out by each other. Likewise, electromagnetic noise generated from the source terminal 520 located in the first distribution space and electromagnetic noise generated from the source terminal 520 located in the second distribution space are likely to be cancelled out by each other. Therefore, the electromagnetic noises generated from the terminals provided in the first distribution space and from the terminals provided in the second distribution space are inhibited from affecting the first gate terminals 541 located between these terminals.

As described above, the two drain terminals 510 are evenly distributed to and placed in the first distribution space and the second distribution space. The two source terminals 520 are evenly distributed to and placed in the first distribution space and the second distribution space.

As a result, compared to a configuration in which the plurality of drain terminals 510 are unevenly distributed only to and placed in either of the first distribution space and the second distribution space, the electromagnetic noises generated from the drain terminals 510 are effectively inhibited from affecting the first gate terminals 541. Compared to a configuration in which the plurality of source terminals 520 are unevenly distributed only to and placed in either of the first distribution space and the second distribution space, the electromagnetic noises generated from the source terminals 520 are effectively inhibited from affecting the first gate terminals 541.

The two midpoint terminals 530 are distributed to the first distribution space and the second distribution space. The second gate terminals 542 are located between the midpoint terminal 530 provided in the first distribution space and the midpoint terminal 530 provided in the second distribution space.

As a result, electromagnetic noises generated from the midpoint terminal 530 located in the first distribution space and electromagnetic noise generated from the midpoint terminal 530 located in the second distribution space are likely to be cancelled out by each other. The electromagnetic noises generated from the midpoint terminal 530 provided in the first distribution space and from the midpoint terminal 530 provided in the second distribution space are inhibited from affecting the second gate terminals 542 located between these terminals.

The sensor terminals 550 are also located between the midpoint terminal 530 provided in the first distribution space and the midpoint terminal 530 provided in the second distribution space. Therefore, the electromagnetic noises generated from the midpoint terminal 530 provided in the first distribution space and from the midpoint terminal 530 provided in the second distribution space are inhibited from affecting the sensor terminals 550.

As described above, the two midpoint terminals 530 are evenly distributed to and placed in the first distribution space and the second distribution space. As a result, compared to a configuration in which the plurality of midpoint terminals 530 are unevenly distributed only to and placed in either of the first distribution space and the second distribution space, the electromagnetic noises generated from the midpoint terminals 530 are effectively inhibited from affecting the second gate terminals 542 and the sensor terminals 550.

The first bent portion 444 and the second bent portion 445 of the first lower current-carrying portion 442 have respective portions each overlapping the second upper current-carrying portion 471 in the z-direction in the overlap areas OA illustrated in FIG. 15. The first bent portion 444 and the second bent portion 445 have respective portions which are aligned with the second upper current-carrying portion 471 in the z-direction via the covering resin 600.

As a result, negative mutual inductance between the first lower current-carrying portion 442 and the second upper current-carrying portion 471 increases. This suppresses an increase in inductance in each of the first lower current-carrying portion 442 and the second upper current-carrying portion 471.

The first current-carrying portion 440 in which the current flows and the first heat dissipating portion 450 having a conductivity are arranged in the z-direction via the first insulating plate 430. Consequently, an eddy current flows in the first heat dissipating portion 450. This suppresses an increase in inductance in the first current-carrying portion 440.

The second current-carrying portion 470 in which the current flows and the second heat dissipating portion 480 having a conductivity are arranged in the z-direction via the second insulating plate 460. Consequently, an eddy current flows in the second heat dissipating portion 480. This suppresses an increase in inductance in the second current-carrying portion 470.

Current-carrying paths for two currents flowing from the drain terminals 510 toward the second semiconductor chips 220 in the y-direction are adjacent to each other in the x-direction. As a result, respective electromagnetic noises emitted from these two current-carrying paths are likely to be cancelled out between the two current-carrying paths.

The source terminals 520 have end portions connected to the first conductive plate 410. Each of the source terminals 520 has a portion located between the second conductive plate 420 and the first conductive plate 410 in the z-direction.

As a result, compared to a configuration in which, e.g., the source terminals 520 are connected to portions of the second conductive plate 420 which do not face the first conductive plate 410 in the z-direction, a physical size increase of the power card 120 is suppressed.

Note that, in the case of the comparative example described above, respective relay members for electrically connecting the first conductive plate 410 and the source terminals 520 are required between the two conductive plates and for the first conductive plate 410. In the present embodiment, the relay members are no longer required. This suppresses an increase in the number of components.

The enclosed area EA defined by the facing portion 731, the first arm portion 732, and the second arm portion 733 each included in the cooling unit 730 and the leading end sides of the plurality of terminals protruding from the lower surface 600d of the covering resin 600 are arranged in the z-direction.

As a result, air located in the enclosed area EA is more likely to be lowered in temperature by the refrigerant flowing the hollows of the three components included in the cooling unit 730. By the air, the leading end sides of the plurality of terminals protruding from the lower surface 600d are more likely to be lowered in temperature.

Each of the second gate terminals 542 and the sensor terminals 550 has a portion located in the enclosed area EA. In addition, each of the U-phase to W-phase bus bars 103 to 105 has a portion located in the enclosed area EA. As a result, by the air located in the enclosed area EA, each of the second gate terminals 542, the sensor terminals 550, and the U-phase to W-phase bus bars 103 to 105 is more likely to be lowered in temperature.

### First Modification

In the present embodiment, an example has been shown in which respective planes of the first heat dissipating portion 450 and the first current-carrying portion 440 which are perpendicular to the z-direction have the same shape. However, the respective planes of the first heat dissipating portion 450 and the first current-carrying portion 440 which are perpendicular to the z-direction need not necessarily have the same shape.

The plane of the first heat dissipating portion 450 which is perpendicular to the z-direction may also has an area larger than that of the plane of the first current-carrying portion 440. It is possible to adopt a configuration in which the first current-carrying portion 440 side of the first heat dissipating portion 450 has an increased area.

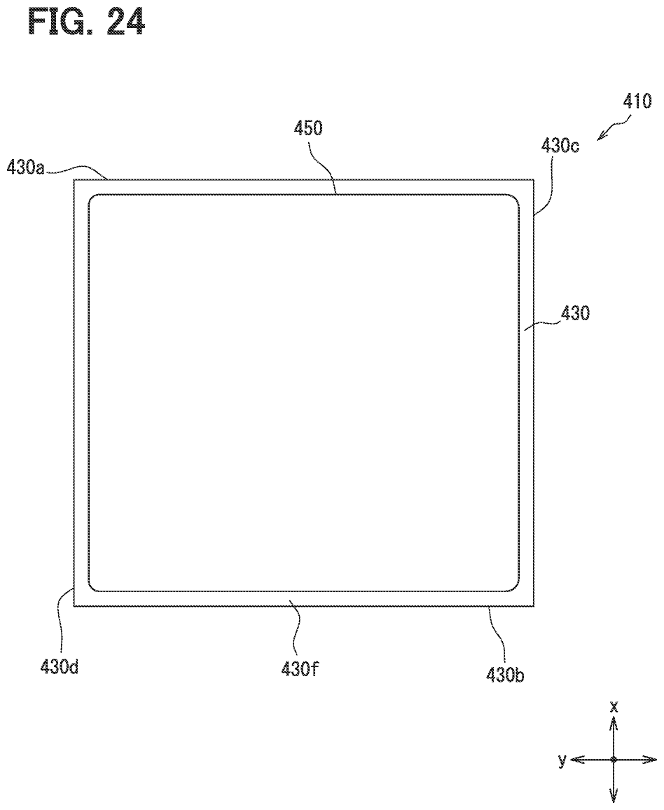

For example, as illustrated in FIG. 24, the first heat dissipating portion 450 may also have a shape formed entirely over the first outer surface 430f of the first insulating plate 430. The first heat dissipating portion 450 may also have a solid pattern. As a result, an eddy current is likely to flow in the first heat dissipating portion 450. An inductance increase in the first current-carrying portion 440 is effectively suppressed.

### Second Modification

In the present embodiment, an example has been shown in which the planes of the second heat dissipating portion 480 and the second current-carrying portion 470 which are perpendicular to the z-direction have the same shape. However, the respective planes of the second heat dissipating portion 480 and the second current-carrying portion 470 which are perpendicular to the z-direction need not necessarily have the same shape.

The plane of the second heat dissipating portion 480 which is perpendicular to the z-direction may also have an area larger than that of the plane of the second current-carrying portion 470 which is perpendicular to the z-direction. It is possible to adopt a configuration in which the second current-carrying portion 470 side of the second heat dissipating portion 480 has an increased area.

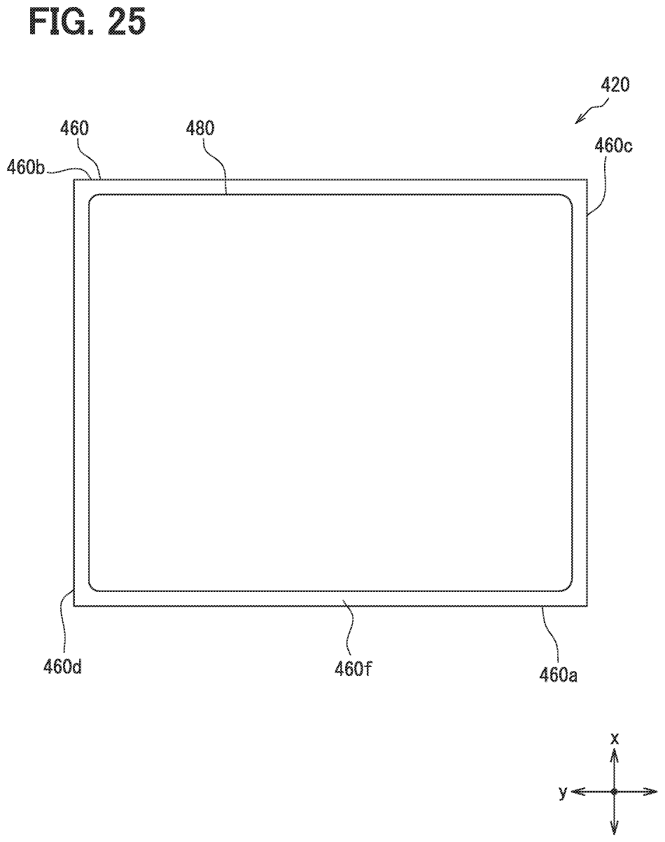

For example, as illustrated in FIG. 25, the second heat dissipating portion 480 may also have a shape formed entirely over the second outer surface 460f of the second insulating plate 460. The second heat dissipating portion 480 may also have a solid pattern. As a result, an eddy current is likely to flow in the second heat dissipating portion 480. An inductance increase in the second current-carrying portion 470 is effectively suppressed.

### Third Modification

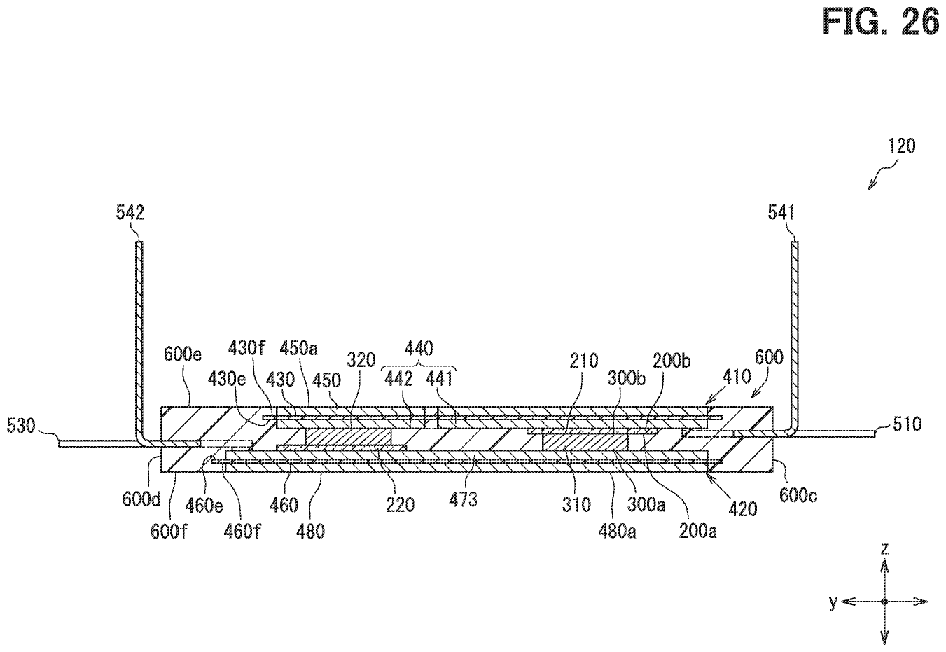

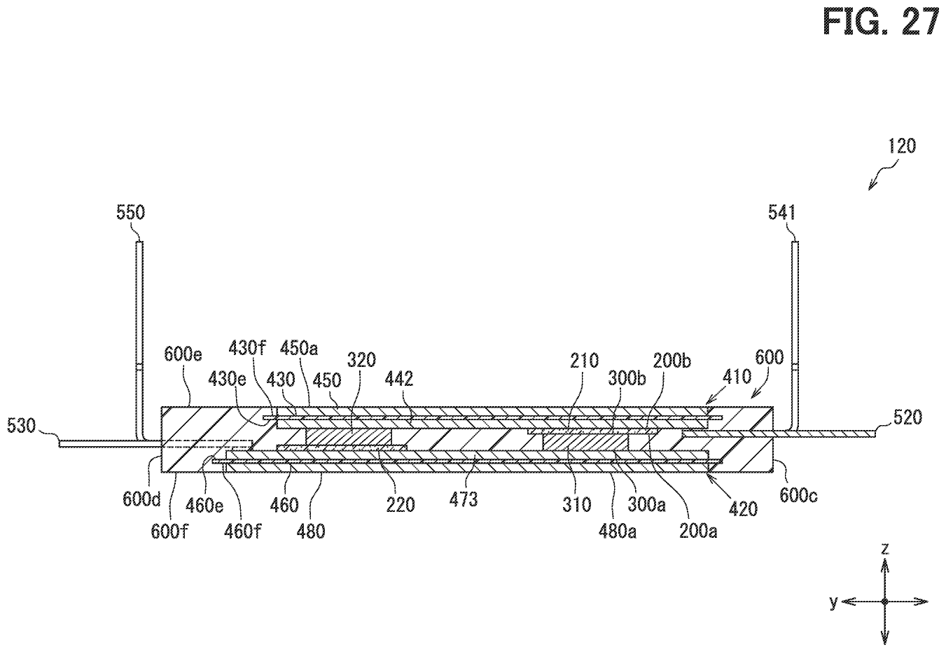

In the present embodiment, an example has been shown in which the first upper current-carrying portion 441 of the first conductive plate 410 and the second lower current-carrying portion 472 of the second conductive plate 420 are electrically connected via the third terminal block 330. However, it may also be possible to omit the third terminal block 330 by adopting the configuration illustrated in, e.g., FIGS. 26 and 27. The cross-sectional view illustrated in FIG. 26 corresponds to a cut section along a line VI-VI illustrated in FIG. 6. The cross-sectional view illustrated in FIG. 27 corresponds to a cut section along a line VII-VII illustrated in FIG. 6.

In the modification illustrated in FIGS. 26 and 27, the second conductive plate 420 has, instead of the second upper current-carrying portion 471 and the second lower current-carrying portion 472, a shared current-carrying portion 473 in which the second upper current-carrying portion 471 and the second lower current-carrying portion 472 are integrally connected. To the shared current-carrying portion 473, the source electrodes 201 of the first semiconductor chips 210 are connected via the first terminal blocks 310. To the first upper current-carrying portion 441, the drain electrodes of the first semiconductor chips 210 are connected.

By adopting such a configuration, the first semiconductor chips 210 and the second semiconductor chips 220 can be electrically connected without interposition of the third terminal block 330. The third terminal block 330 can be omitted.

Note that the first upper current-carrying portion 441 is elongated to the first upper surface 430c side in the y-direction compared to that in the configuration illustrated in FIG. 8. To respective portions of the first upper current-carrying portion 441 which are aligned in the x-direction with respective end portions of the first bent portion 444 and the second bent portion 445 which are on the first upper surface 430c side, the drain terminals 510 are connected.

In this modification, in respective regions where the first bent portion 444 and the second bent portion 445 of the first lower current-carrying portion 442 are projected in the z-direction, portions of the shared current-carrying portion 473 are located. In the same manner as in the present embodiment, the first heat dissipating portion 450 is aligned with the first current-carrying portion 440 in the z-direction, while the second heat dissipating portion 480 is aligned with the second current-carrying portion 470 in the z-direction. Note that, as a matter of course, it is also possible to adopt a configuration obtained by vertically inverting the configuration illustrated in FIGS. 26 and 27.

The first upper current-carrying portion 441 corresponds to the first conductive portion. Each of the first terminal blocks 310 and the shared current-carrying portion 473 correspond to the second conductive portion. Each of the second terminal blocks 320 and the first lower current-carrying portion 442 correspond to the third conductive portion.

### Fourth Modification

In the present embodiment, an example has been shown in which the power card 120 has the two first semiconductor chips 210 and the two second semiconductor chips 220. However, the respective numbers of the first semiconductor chips 210 and the second semiconductor chips 220 which are included in the power card 120 are not limited thereto. The power card 120 may also have the one first semiconductor chip 210 and the one second semiconductor chip 220 or the three or more first semiconductor chips 210 and the three or more second semiconductor chips 220. The one power card 120 needs only to have a plurality of semiconductor chips of the same type or different types which are arranged in the y-direction.

The power card 120 may also have the one high-side switch 141 and the one low-side switch 151 or the three or more high-side switches 141 and the three or more low-side switches 151. The one power card 120 needs only to have a plurality of switches of the same type or different types which are arranged in the y-direction.

### Fifth Modification

In the present embodiment, an example has been shown in which the power card 120 has the temperature sensor 160. However, the power card 120 need not necessarily have the temperature sensor 160. In the case of this modification, the power card 120 does not have the sensor terminals 550.

In the present embodiment, an example has been shown in which the temperature sensor 160 is formed in each of the second semiconductor chips 220. However, the temperature sensor 160 need not necessarily be formed in the second semiconductor chip 220. The temperature sensor 160 may also be formed in each of the first semiconductor chips 210. The temperature sensor 160 may also be formed separately from each of the first semiconductor chips 210 and the second semiconductor chips 220.

Alternatively, it is also possible to adopt a configuration in which the power card 120 has a physical quantity sensor that detects a physical quantity different from that detected by the temperature sensor 160. Examples of the different physical quantity include a current, a voltage, and the like.

### Sixth Modification

In the present embodiment, an example has been shown in which the power card 120 has the two midpoint terminals 530. However, the power card 120 may also have the one midpoint terminal 530.

### Seventh Modification

In the present embodiment, an example has been shown in which the power card 120 has the two source terminals 520. However, the power card 120 may also have the one source terminal 520.

### Eighth Modification

In the present embodiment, an example has been shown in which the power card 120 has the two drain terminals 510. However, the power card 120 may also have the one drain terminal 510.

### Ninth Modification

In the present embodiment, an example has been shown in which the two drain terminals 510 and the two first gate terminals 541 are located between the two source terminals 520 while, between the two drain terminals 510, the two first gate terminals 541 are located. However, it is also possible to adopt a configuration in which, between the two drain terminals 510, the two source terminals 520 and the two first gate terminals 541 are located while, between the two source terminals 520, the two first gate terminals 541 are located.

### Other Modifications

In the present embodiment, an example has been shown in which, as the respective switches included in the U-phase to W-phase semiconductor modules 121 to 123, the n-channel MOFETs are adopted. However, the types of the respective switches included in the 3-phase semiconductor modules are not particularly limited. As the switches, e.g., IGBTs can be adopted. The types of the respective switches included in the 3-phase semiconductor modules may be or may not be the same.

In the present embodiment, an example has been shown in which the first semiconductor chips 210 are formed with the high-side switches 141 and the high-side diodes 142. However, the high-side switches 141 and the high-side diodes 142 may also be formed in another semiconductor chip.

In the present embodiment, an example has been shown in which the second semiconductor chips 220 are formed with the low-side switches 151 and the low-side diodes 152. However, the low-side switches 151 and the low-side diodes 152 may also be formed in another semiconductor chip.

In the present embodiment, an example has been shown in which the inverter is included in the power conversion device 50. However, in addition to the inverter, a converter may also be included in the power conversion device 50.

In the present embodiment, an example has been shown in which the power conversion unit 30 is included in the in-vehicle system 10 of the electric vehicle. However, an application of the power conversion unit 30 is not particularly limited to that in the example described above. For example, it is also possible to adopt a configuration in which the power conversion unit 30 is included in a hybrid system including a motor and an internal combustion engine.

In the present embodiment, an example has been shown in which the one motor 40 is connected to the power conversion unit 30. However, it is also possible to adopt a configuration in which a plurality of the motors 40 are connected to the power conversion unit 30. In this case, the power conversion unit 30 has a plurality of the 3-phase semiconductor modules each for configurating an inverter.

While the present disclosure has been described with reference to embodiments thereof, it is to be understood that the disclosure is not limited to the embodiments and constructions. The present disclosure is intended to cover various modification and equivalent arrangements. In addition, while the various combinations and configurations have been shown in the present disclosure, other combinations and configurations, including more, less or only a single element, are also within the scope and spirit of the present disclosure.

What is claimed is:

1. A power card, which is to be aligned in a height direction with a cooling unit in which a refrigerant flows in an inner space extending in a lateral direction, the height direction being perpendicular to the lateral direction, the power card comprising:
a plurality of switches aligned in a vertical direction perpendicular to each of the lateral direction and the height direction;
a resin portion covering each of the plurality of switches; and
a plurality of external connection terminals electrically connected to the plurality of respective switches and each having a portion exposed from the resin portion.

2. The power card according to claim 1,
wherein the resin portion has an upper surface and a lower surface which are spaced apart from each other in the vertical direction,
wherein the plurality of switches include a first switch located adjacent to the upper surface of the resin portion in the vertical direction and a second switch located adjacent to the lower surface of the resin portion in the vertical direction, and
wherein the plurality of external connection terminals each have a leading end protruding from at least one of the upper surface and the lower surface of the resin portion.

3. The power card according to claim 2,
wherein the first switch includes a plurality of the first switches and the second switch includes a plurality of the second switches,
wherein each of the plurality of first switches has a first electrode, a second electrode, and a first control electrode for controlling an energized state between the first electrode and the second electrode,
wherein each of the plurality of second switches has a third electrode, a fourth electrode, and a second control electrode for controlling an energized state between the third electrode and the fourth electrode,
wherein the respective first electrodes of the plurality of first switches are electrically connected to each other and the respective second electrodes of the plurality of first switches are connected to each other to connect the plurality of first switches in parallel,
wherein the respective third electrodes of the plurality of second switches are electrically connected to each other and the respective fourth electrodes of the plurality of second switches are connected to each other to connect the plurality of second switches in parallel, and
wherein the respective second electrodes of the plurality of first switches are electrically connected to the respective third electrodes of the plurality of second switches to connect, in series, the plurality of first switches connected in parallel to the plurality of second switches connected in parallel.

4. The power card according to claim 2,
wherein the first switch has a first electrode, a second electrode, and a first control electrode for controlling an energized state between the first electrode and the second electrode,
wherein the second switch has a third electrode, a fourth electrode, and a second control electrode for controlling an energized state between the third electrode and the fourth electrode, and
wherein the second electrode and the third electrode are electrically connected to each other to connect the first switch in series to the second switch.

5. The power card according to claim 3,
wherein the plurality of external connection terminals include a positive electrode terminal electrically connected to at least one of the first electrodes, a negative electrode terminal electrically connected to at least one of the fourth electrodes, a midpoint terminal electrically connected to at least one of the second electrodes and at least one of the third electrodes, a first control terminal electrically connected to at least one of the first control electrodes, and a second control terminal electrically connected to at least one of the second control electrodes,
wherein the positive electrode terminal, the negative electrode terminal, and the first control terminal have respective leading ends protruding from the upper surface of the resin portion, and
wherein the midpoint terminal and the second control terminal have respective leading ends protruding from the lower surface of the resin portion.

6. The power card according to claim 5,
wherein at least one of the positive electrode terminal and the negative electrode terminal has a plurality of the leading ends branched from each other,
wherein the plurality of leading ends of the at least one of the positive electrode terminal and the negative electrode terminal are distributed to and placed in a first distribution space and a second distribution space which are separated by a reference plane perpendicular to the lateral direction, and
wherein, in the lateral direction, the first control terminal is located between the leading end of the at least one of the positive electrode terminal and the negative electrode terminal placed in the first distribution space and the leading end of the at least one of the positive electrode terminal and the negative electrode terminal placed in the second distribution space.

7. The power card according to claim 6,
wherein each of the positive electrode terminal and the negative electrode terminal has a plurality of the leading ends branched from each other,
wherein the plurality of leading ends of the positive electrode terminal are distributed to and placed in the first distribution space and the second distribution space, and
wherein the plurality of leading ends of the negative electrode terminal are distributed to and placed in the first distribution space and the second distribution space.

8. The power card according to claim 7,
wherein the plurality of leading ends of at least one of the positive electrode terminal and the negative electrode terminal are evenly distributed to and placed in the first distribution space and the second distribution space.

9. The power card according to claim 7,
wherein, in the lateral direction, the plurality of leading ends of one of the positive electrode terminal and the negative electrode terminal are all located between the leading end of the other one of the positive electrode terminal and the negative electrode terminal distributed to and placed in the first distribution space and the leading end of the other one of the positive electrode terminal and the negative electrode terminal distributed to and placed in the second distribution space.

10. The power card according to claim 5,
wherein the midpoint terminal has a plurality of the leading ends branched from each other, and
wherein, in the lateral direction, the second control terminal is located between the plurality of leading ends of the midpoint terminal.

11. The power card according to claim 10,
wherein, in the lateral direction, the plurality of leading ends of the midpoint terminal are evenly distributed across the second control terminal.

12. The power card according to claim 10, further comprising:
a sensor that detects a physical quantity of at least one of the switches,
wherein the sensor includes a sensor terminal having a leading end, and
wherein the leading end of the sensor terminal protrudes from the lower surface of the resin portion and is located between the plurality of leading ends of the midpoint terminal in the lateral direction.

13. The power card according to claim 5, further comprising:
a first semiconductor chip including the first switch, and having a first main surface which is formed with the first electrode and a second main surface which is opposite to the first main surface and formed with the second electrode;
a second semiconductor chip including the second switch, and having a third main surface which is formed with the third electrode and a fourth main surface which is opposite to the third main surface and formed with the fourth electrode;
a first conductive portion connected to the first electrode;
a second conductive portion connected to the second electrode;
a third conductive portion connected to the third electrode;
a fourth conductive portion connected to the fourth electrode; and
a relay conductive portion connecting the second conductive portion and the third conductive portion.

14. The power card according to claim 13,
wherein the first conductive portion has a part located in a region where the fourth conductive portion is projected in the height direction.

15. The power card according to claim 13, further comprising:
a first insulating plate having a first inner surface on which the first conductive portion and the third conductive portion are mounted;
a first heat dissipating portion mounted on a first outer surface of the first insulating plate opposite to the first inner surface, and aligned with the first conductive portion and the third conductive portion in the height direction;
a second insulating plate having a second inner surface on which a part of the second conductive portion and a part of the fourth conductive portion are mounted; and
a second heat dissipating portion mounted on a second outer surface of the second insulating plate opposite to the second inner surface, and aligned with the second conductive portion and the fourth conductive portion in the height direction.

16. The power card according to claim 5, further comprising:
a first semiconductor chip including the first switch, and having a first main surface which is formed with the first electrode and a second main surface which is opposite to the first main surface and formed with the second electrode;
a second semiconductor chip including the second switch, and having a third main surface which is formed with the third electrode and a fourth main surface which is opposite to the third main surface and is formed with the fourth electrode;
a first conductive portion connected to the first electrode;
a second conductive portion connected to each of the second electrode and the third electrode; and
a third conductive portion connected to the fourth electrode.

17. The power card according to claim 16,
wherein the second conductive portion has a part located in a region where the third conductive portion is projected in the height direction.

18. The power card according to claim 16, further comprising:
a first insulating plate having a first inner surface on which the first conductive portion and the third conductive portion are mounted;
a first heat dissipating portion mounted on a first outer surface of the first insulating plate opposite to the first inner surface, and aligned with the first conductive portion and the third conductive portion in the height direction;
a second insulating plate having a second inner surface on which the second conductive portion is mounted; and
a second heat dissipating portion mounted on a second outer surface of the second insulating plate opposite to the second inner surface, and aligned with the second conductive portion in the height direction.

19. The power card according to claim 15,
wherein each of the plurality of external connection terminals has a portion located between the first insulating plate and the second insulating plate.
